(19) United States
(12) Patent Application Publication
(10) Pub. No.: US 2026/0176401 A1
(43) Pub. Date: Jun. 25, 2026

(54) DSA OF LIQUID CRYSTAL BLOCK COPOLYMERS FOR INTEGRATED CIRCUIT PATTERNING

(71) Applicant: Merck Patent GmbH, Darmstadt (DE)

(72) Inventors: Ralph R. DAMMEL, Springfield, PA (US); Sophia BUHBUT, Ashkelon (IL); Alex IRZH, Rehovot (IL); Miriam KOOLYK SHARABI, Jerusalem (IL); Sina NOLL, Sulzbach (DE); Shany NEYSHTADT, Haifa (IL)

(21) Appl. No.: 19/126,113

(22) PCT Filed: Nov. 9, 2023
(86) PCT No.: PCT/EP2023/081274

§ 371 Date: Apr. 30, 2025

Related U.S. Application Data
(60) Provisional application No. 63/383,379, filed on Nov. 11, 2022.

(51) Int. Cl. C08F 293/00; C08F 212/08; C08F 220/20; H10P 76/40

(52) U.S. Cl. CPC C08F 293/00; C08F 212/08; C08F 220/20; C08F 293/005; H10P 76/4085

(57) ABSTRACT

Described is a block copolymer, which is an AB diblock copolymer with a first block A of structure (I) and a second block B of structure (II), wherein R and Ri are individually selected from a C-1 to C-4 alkyl, where the mole % of repeat units of structure (I) ranges from about 35 mole % to about 94 mole %, and the mole % of repeat units of structure (II) ranges from about 6 mole % to about 65 mole %, R₂ is selected from a C-1 to C-11 alkyl, L is a C-5 to C-12 linear alkylene, and R₃ is selected from a C-3 to C-8 linear alkyl, R is H or a C-3 to C-8 linear alkyl wherein said block copolymer has a poly dispersity of 1 to about 1.31. Also described are compositions of this block copolymer in a solvent and their use in DSA processing.

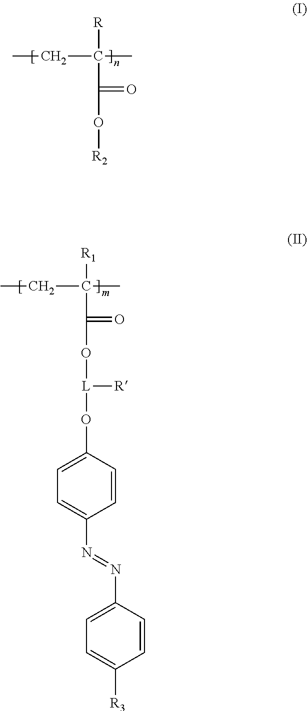

### FIELD

The disclosed and claimed subject matter pertains block copolymers with liquid crystal pendant group and compositions of these in an organic spin casting film, the process for forming directed self-assembled block copolymers films on a substrate using these compositions.

### RELATED ART

In the last decades, many efforts have been made to further increase miniaturization, cost, speed, power consumption and versatility concerning the silicon based integrated circuits industry (IC). Tremendous progress has been made to increase the numbers of transistors per CPU, and today microprocessors contain up to four billion transistors per small unit area. To build these kinds of processors, a series of operations is performed; among the process steps are photolithography, etching and deposition. Photolithography is a key step in the production of transistors and resistors. The main factor effecting resolution of the obtained structures is the illumination wavelength used during photolithography. The smaller the wavelength, the higher the possible resolution, and the smaller the pitch size. Currently, 193 nm is the smallest illumination wavelength which has been introduced in IC, and it can provide ˜80 nm pitch; however, the industry target today is to achieve pitch sizes of single nanometers for the same unit area.

To avoid the investment in new equipment and materials, multiple patterning photolithography techniques have been introduced, and have achieved pitches of ˜40 nm. But multiple patterning comes at the cost of increased number of steps, defects, cost, process time, tools, fab space, consumable materials, and personnel.

In conventional lithography approaches, ultraviolet (UV) radiation may be used to expose through a mask onto a photoresist layer coated on a substrate or layered substrate. Positive or negative photoresists are useful, and these can also contain a refractory element such as silicon to enable dry development with conventional integrated circuit (IC) plasma processing. In a positive photoresist, UV radiation transmitted through a mask causes a photochemical reaction in the photoresist such that the exposed regions are removed with a developer solution or by conventional IC plasma processing. Conversely, in negative photoresists, UV radiation transmitted through a mask causes the regions exposed to radiation to become less removable with a developer solution or by conventional IC plasma processing. An integrated circuit feature, such as a gate, via or interconnect, is then etched into the substrate or layered substrate, and the remaining photoresist is removed. When using conventional lithographic exposure processes, the dimensions of features of the integrated circuit feature are limited. Further reduction in pattern dimensions is difficult to achieve with radiation exposure due to limitations related to aberrations, focus, proximity effects, minimum achievable exposure wavelengths and maximum achievable numerical apertures. Directed self-assembly is a promising approach which has been of interest in in overcoming some of the drawback of conventional lithography as outlined above. Directed self-assembly of block copolymers is a method useful for generating smaller and smaller patterned features for the manufacture of microelectronic devices in which the critical dimensions (CD) of features on the order of nanoscale can be achieved. Directed self-assembly methods are desirable for extending the resolution capabilities of microlithographic technology. The need for large-scale integration has led to a continued shrinking of the circuit dimensions and features in the devices. In the past, the final resolution of the features has been dependent upon the wavelength of light used to expose the photoresist, which has its own limitations. The most recent technique for achieving the targeted pitches using shorter wavelengths of light is Extreme Ultraviolet Lithography (EUV), which could theoretically achieve a maximum pitch resolution of ˜13.5 nm. However, this technique has high defectivity, which is not compatible with industry expectations. The defectivity specific to EUV is generalized as mask defectivity, and is a combination of substrate, multilayer blank, and absorber patterning defects. Additionally, this technique is especially high cost, with only 53 machines worldwide capable of production. Direct assembly techniques, such as graphoepitaxy and chemoepitaxy using block copolymer imaging, are highly desirable techniques used to enhance resolution while reducing CD variation. These techniques can be employed to either enhance conventional UV lithographic techniques or to enable even higher resolution and CD control in approaches employing EUV, e-beam, deep UV, or immersion lithography.

Directed self-assembly (DSA) of Block copolymer (BCP) lithography is an additional alternative or complement to conventional lithography's, which differs from the methods mentioned above in that it involves a combination of bottom-up and top-down methods. Templates created with photolithography/EUV techniques (top-down methods) are spin-coated with the BCP, which is then made to phase separate under the influence of the guiding patterns (templates) at very high resolution of single nanometers (bottom-up). Afterwards, one block is selectively etched, and a desired pitch pattern is obtained in accordance with the size of the block.

Block copolymers (BCP) are composed of at least two different homopolymers, which are linked by a covalent bond. Under certain conditions, the BCP self-assembles into nanodomain patterns with vertical lamellar meso-structure. This case allows for selective etching of one block down to the substrate, such that the remaining block is repeated at a constant pitch of single nanometers. The advantages of DSA using BCPs stem from it being a bottom-up technology in which the pattern is determined by the material properties, rather than the equipment. These advantages are low defectivity, high efficiency, and low cost.

A directed self-assembly block copolymer comprises a block of etch resistant copolymeric unit and a block of highly etchable copolymeric unit, which when coated, aligned and etched on a substrate give regions of very high-density patterns. The directed self-assembly block copolymer comprises a block of etch resistant copolymeric unit and a block of highly etchable copolymeric unit, which when coated, aligned and etched on a substrate give regions of very high-density patterns.

To achieve the standing lamellar meso-structures required for patterning by selective etching, control of three BCP parameters is critical: The molecular weight (Mₙ), the chemical interaction between the blocks (χ), and the volume ratio (f) of the blocks.

Various block copolymers with low Chi have been described and claimed for their use in semiconductor patterning, such as PS-PMMA, PS-PLA, PS-PVP, etc.

The ability of a BCP to phase separate depends on the Flory Huggins interaction parameter (χ). PS-b-PMMA (poly(styrene-block-methyl methacrylate) is the most promising candidate for directed self-assembly (DSA) applications. However, the minimum half-pitch of PS-b-PMMA is limited to about 10 nm because of lower interaction parameter ( [symbol] ) between PS and PMMA. To enable further feature miniaturization, a block copolymer with a larger interaction parameter between two blocks (higher chi) is highly desirable.

Specifically, directed self-assembly of block copolymers is a method useful for generating very small, patterned features for the manufacture of microelectronic devices in which the critical dimensions (CD) of features usually on the order of nano scale ranging in feature size from 10 nm to 50 nm can be achieved. Achieving feature sizes below 10 nm using conventional approaches for directed self-assembly of block copolymers is challenging. Directed self-assembly methods such as those based on graphoepitaxy, and chemical epitaxy of block copolymers are desirable for extending the resolution capabilities of lithographic technology.

These techniques can be employed to either enhance conventional lithographic techniques by enabling the generation of pattern with higher resolution and/or improving CD control for EUV, e-beam, deep UV, or immersion lithography. The directed self-assembly block copolymer comprises a block of etch resistant polymeric unit and a block of highly etchable polymeric unit, which when coated, aligned and etched on a substrate give regions of high-resolution patterns.

Known examples of block copolymers suitable for directed self-assembly are ones capable of microphase separation and comprising a block rich in carbon (such as styrene or containing some other element like Si, Ge, and Ti) which is resistant to plasma etch, and a block which is highly plasma etchable or removable, which can provide a high-resolution pattern definition. Examples of highly etchable blocks can comprise monomers which are rich in oxygen, and which do not contain refractory elements and are capable of forming blocks which are highly etchable, such as methyl methacrylate. The plasma etching gases used in the etching process of defining the self-assembly pattern typically are those used in processes to make integrated circuits (IC). In this manner very fine patterns can be created on typical IC substrates compared to conventional lithographic techniques, thus achieving pattern multiplication.

In the graphoepitaxy directed self-assembly method, the block copolymers self-organize on a substrate that is pre-patterned with conventional lithography (e.g., Ultraviolet, Deep UV, e-beam, and EUV exposure sources) to form topographical features such as a line/space (L/S) or contact hole (CH) pattern. In an example of L/S directed self-assembly array, the block copolymer can form self-aligned lamellar regions with a sub-lithographic pitch in the trenches between sidewalls of pre-pattern, thus enhancing pattern resolution by subdividing the space in the trench between the topographical lines into finer patterns. Similarly, features such as contact holes can be made denser by using graphoepitaxy in which a suitable block copolymer arranges itself by directed self-assembly within an array of pre-patterned holes or pre-patterned posts defined by conventional lithography, thus forming a denser array of regions of etchable and etch resistant domains which when etched give rise to a denser array of contact holes. In addition, block copolymers can form a single and smaller etchable domain at the center of prepattern hole with proper dimension and provide potential shrink and rectification of the hole in prepattern. Consequently, graphoepitaxy has the potential to offer both pattern rectification and pattern multiplication.

In chemical epitaxy (chemoepitaxy) DSA methods, the self-assembly of the block copolymer occurs on a surface that has regions of differing chemical affinity but no or very slight topography to guide the self-assembly process. For example, the chemical prepattern could be fabricated using lithography (UV, Deep UV, e-beam, EUV) and nanofabrication process to create surfaces of different chemical affinity in a line and space (L/S) pattern. These areas may present little to no topographical difference but do present a surface chemical pattern to direct self-assembly of block copolymer domains. This technique allows precise placement of these block copolymer domains of higher spatial frequency than the spatial frequency of the prepattern. The aligned block copolymer domains can be subsequently pattern transferred into an underlying substrate after plasma or wet etch processing. In addition, Chemical epitaxy has the advantage that the block copolymer self-assembly can rectify variations in the surface chemistry, dimensions, and roughness of the underlying chemical pattern to yield improved line-edge roughness and CD control in the final self-assembled block copolymer domain pattern. Other types of patterns such as contact holes (CH) arrays could also be generated or rectified using chemoepitaxy.

For lithography applications, orientation of the block copolymer domains perpendicular to the substrate is desirable. For a conventional block copolymer such as PS-b-PMMA in which both blocks have similar surface energies at the BCP-air interface, this can be achieved by coating and thermally annealing the block copolymer on a layer of non-preferential or neutral material that is grafted or crosslinked at the polymer-substrate interface. Due to larger difference in the interaction parameter between the domains of higher-Chi block copolymers, it is important to control both BCP-air and BCP-substrate interactions. Many orientation control strategies for generating perpendicularly oriented BCP domains have been implemented with higher-Chi BCPs. For example, solvent vapor annealing has been used for orientation control of polystyrene-b-polyethylene oxide (PS-b-PEO), polystyrene-b-polydimethylsiloxane (PS-b-PDMS), polystyrene-b-poly(2-vinyl pyridine) (PS-b-P2VP), polylactide-b-poly(trimethylsilylstyrene) PLA-b-PTMSS and PDMS-b-PHOST. Introducing a solvent vapor chamber and kinetics of solvent vapor annealing may complicate DSA processing. Alternatively, the combination of neutral underlayers and topcoat materials has been applied to PS-b-P2VP, PS-b-PTMSS and PLA-b-PTMSS to achieve perpendicular orientation of the polymer domains. However, the additional topcoat materials may increase the process cost and complexity. Thus, there exists a need to have a topcoat free higher-Chi BCP system using simple thermal annealing on a range of preferential and non-preferential substrates. One crucial factor in the past to allow proper perpendicular orientation of the block copolymer domains even for high Chi polymers is the nature of the interaction between the different domains and the substate it is coated on. Specifically, the surface must not prefer either one of the domains otherwise these will not orient in a perpendicular direction during self-assembly, it needs to be neutral towards its interactions with the two domains. To prepare such a neutral surface grafting of polymer brushes on the surface of Silicon or Silicon dioxide (SiOx) substrates can be employed for the formation of neutral layer on these surfaces which allow block copolymer to orient their domains perpendicular to the substrate surface during self-assembly or directed self-assembly. More specifically, these neutral layers are layers on a substrate or the surface of a treated substrate which have no affinity for either of the block segment of a block copolymer employed in directed self-assembly. In the graphoepitaxy method of directed self-assembly of block copolymer, neutral layers are useful as they allow the proper placement or orientation of block copolymer segments for directed self-assembly which leads to proper placement of etch resistant block copolymer segments and highly etchable block copolymer segments relative to the substrate. For instance, in surfaces containing line and space features which have been defined by conventional radiation lithography, a neutral layer allows block segments to be oriented so that the block segments are oriented perpendicular to the surface of the substrates, an orientation which is ideal for both pattern rectification and pattern multiplication depending on the length of the block segments in the block copolymer as related to the length between the lines defined by conventional lithography. If a substrate interacts too strongly with one of the block segments it would cause it to lie flat on that surface to maximize the surface of contact between the segment and the substrate; such a surface would perturb the desirable perpendicular alignment which can be used to either achieve pattern rectification or pattern multiplication based on features created through conventional lithography. Modification of selected small areas or pinning of substrate to make them strongly interactive with one block of the block copolymer and leaving the remainder of the surface coated with the neutral layer can be useful for forcing the alignment of the domains of the block copolymer in a desired direction, and this is the basis for the pinned chemoepitaxy or graphoepitaxy employed for pattern multiplication. However, the requirement of a neutral layer on a treated substrate requires additional processing step. Thus, there is a need for novel block copolymer which can undergo self-assembly and directed self-assembly on a treated substrate without a neutral layer as this reduces the number of steps required for DSA processing increasing throughput of IC manufacturing.

### DETAILED DESCRIPTION OF DRAWINGS

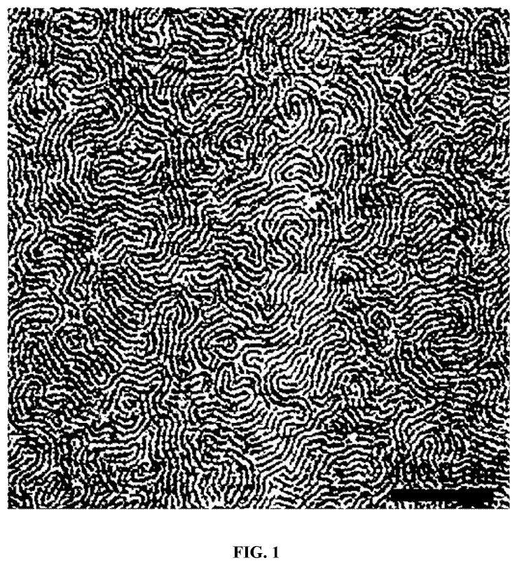

FIG. 1 AFM pictures of self-assembled film of EX. 1 after annealing.

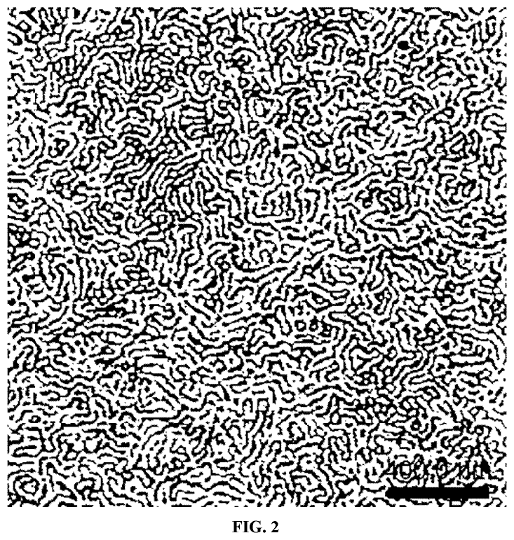

FIG. 2 AFM pictures of self-assembled film of EX. 5 after annealing.

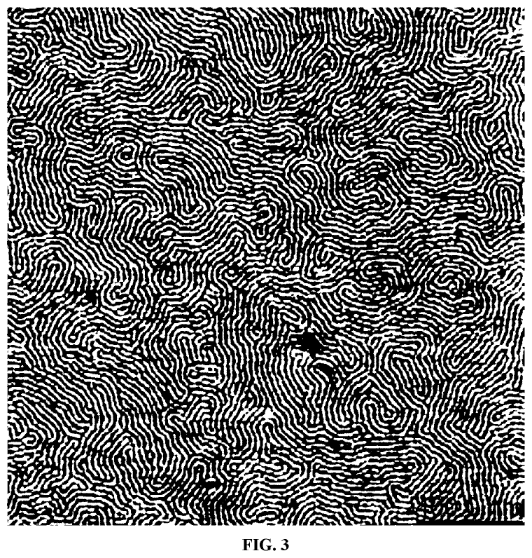

FIG. 3 AFM pictures of self-assembled film of EX. 9 after annealing.

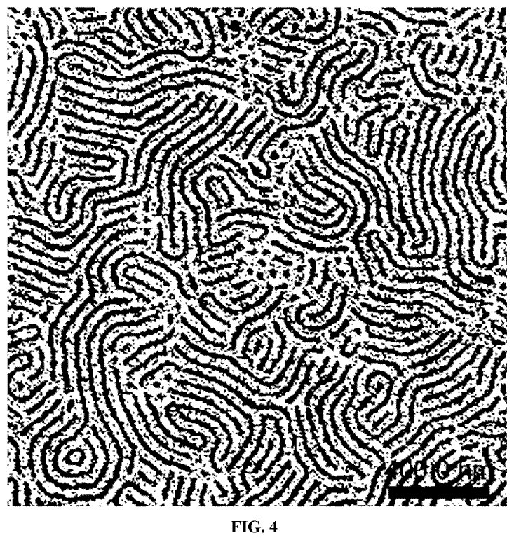

FIG. 4 AFM pictures of self-assembled film of EX. 15 after annealing.

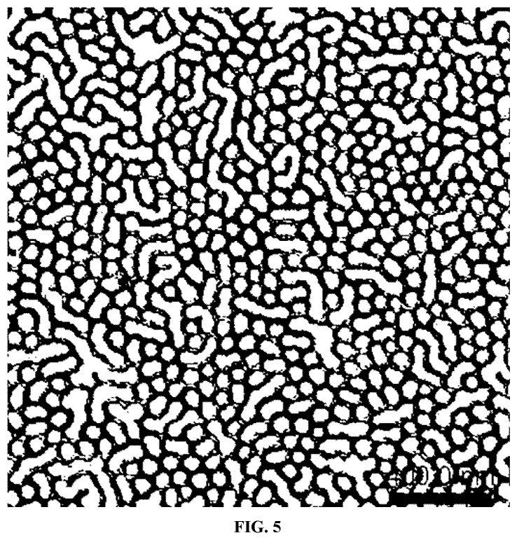

FIG. 5 AFM pictures of self-assembled film of EX. 16 after annealing.

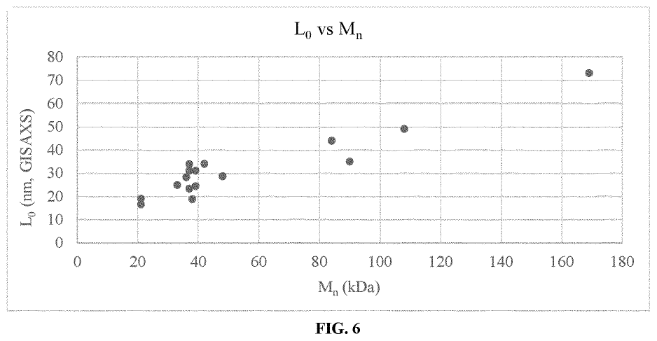

FIG. 6: Graph of L₀ vs Mn for lamellar block copolymers of Table 1 after coating and annealing on bare SiO or SiN;

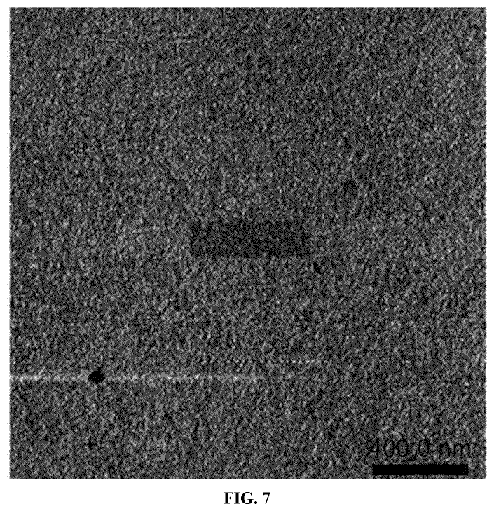

FIG. 7 AFM pictures of self-assembled film of COMP. EX. 1 after annealing.

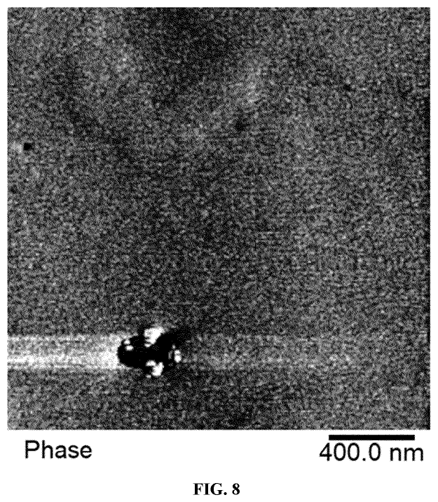

FIG. 8 AFM pictures of self-assembled film of COMP. EX. 2 after annealing.

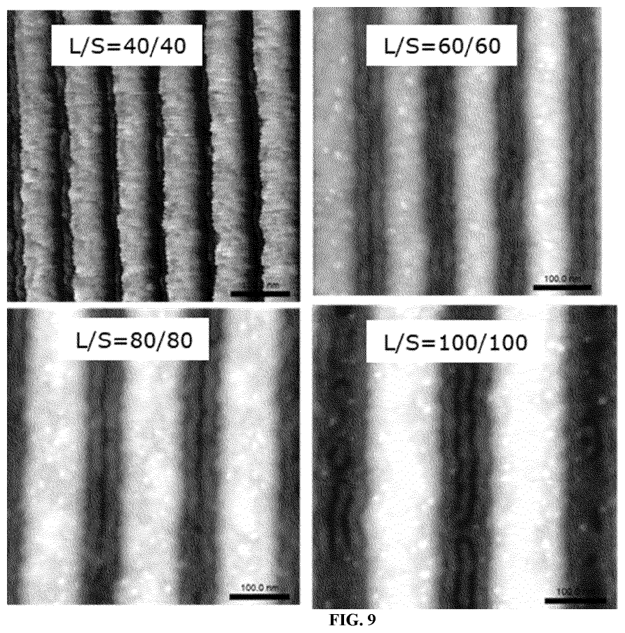

FIG. 9: DSA of Block Copolymer EX. 1 on Graphoepitaxy Substrates with trench/plateau dimensions of 40/40, 60/60, 80/80, 100/100 nm from left to right.

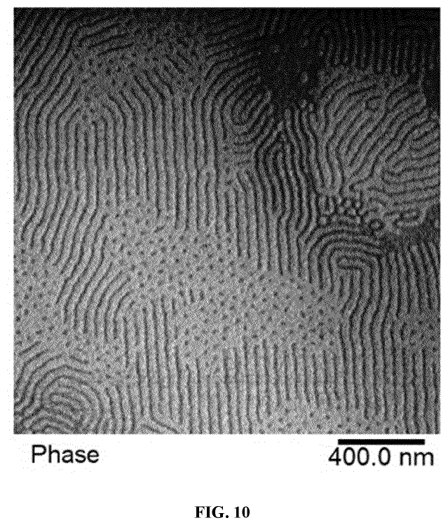

FIG. 10: Partial DSA over chemoepitaxy substrates EX. 15.

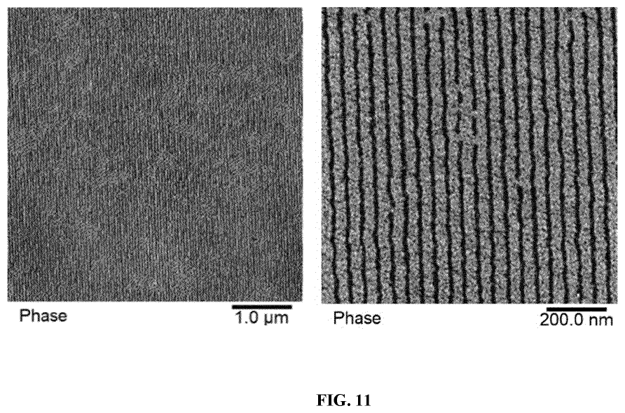

FIG. 11: DSA over chemoepitaxy substrates low and high AFM magnification EX15.

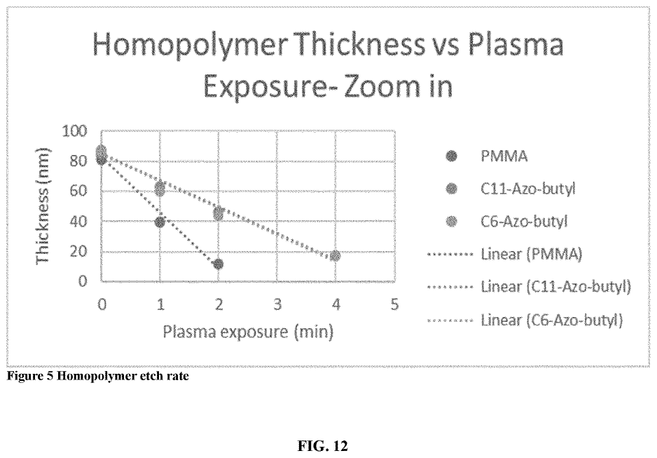

FIG. 12: Comparison of Plasma Etch rate for PMMA, P[MA-C6-Azobutyl] and P[MA-C11-Azobutyl].

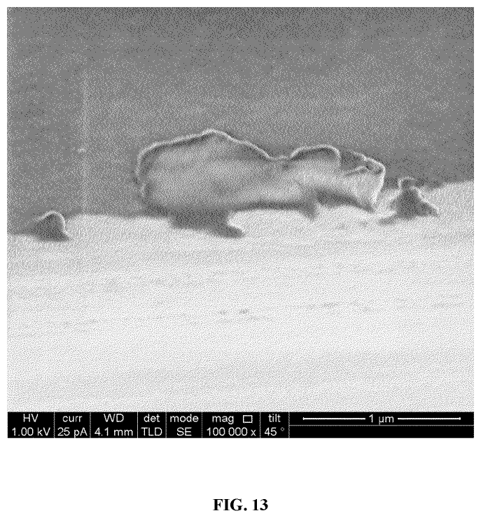

FIG. 13 Continuous film of annealed film of EX. 11 pre-etch.

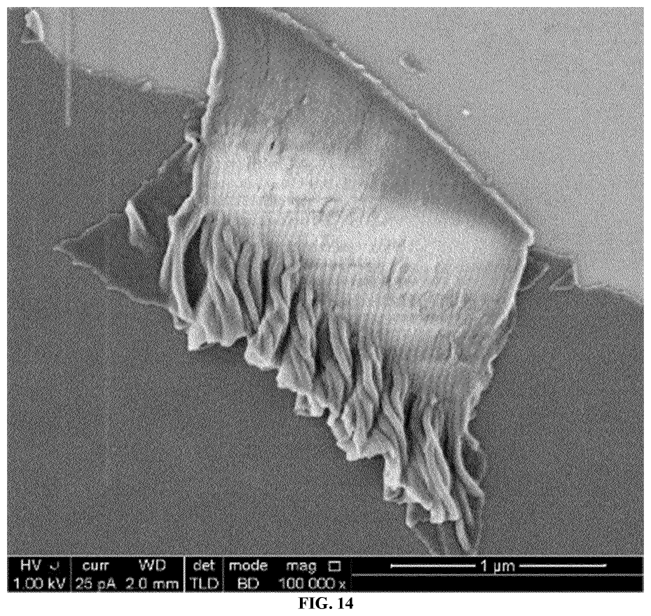

FIG. 14 Continuous film of annealed film of EX. 11 after plasma-etch.

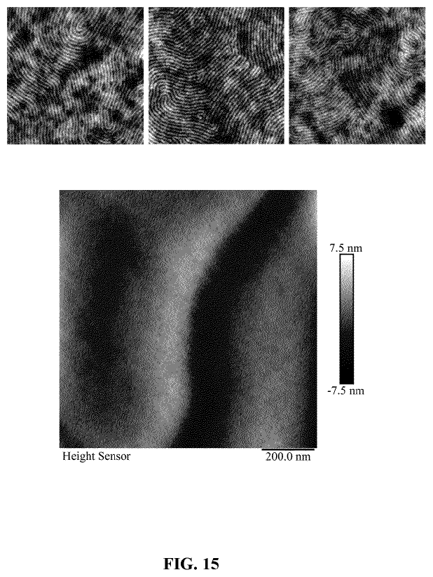

FIG. 15 AFM of Fingerprint self-assembled films of PMMA-b-P[MA C6 Azobutyl] Left to right EX. 17, EX. 18. EX. 19, Bottom EX. 20, 1 wt. % 190° C. 1 hr over SiN; lumx lum scans.

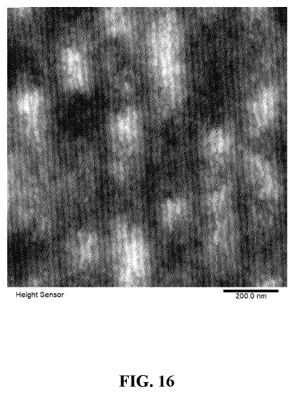

FIG. 16 AFM of Graphoepitaxy of PMMA-b-P[MA C6 Azobutyl] with L₀ 23 nm (EX. 17, Mn 35 kDa), 1 wt. % 190° C. 1 hr over 80 nm trench/plateau in SiOx.

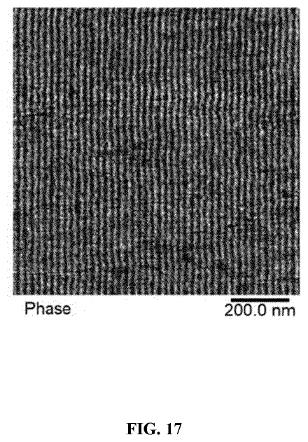

FIG. 17 AFM of Chemoepitaxy of PMMA-b-P[MA C6 Azobutyl] with L₀ 23 nm (EX. 17, Mn 35 kDa), 1 wt. % 190° C. 1 hr over xPMMA of pitch 90 nm, width 26 nm.

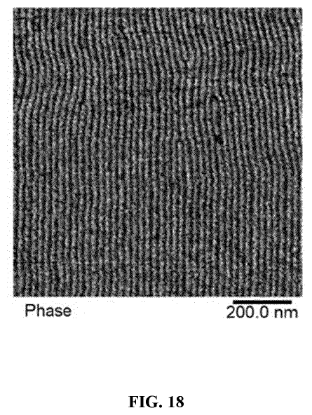

FIG. 18 AFM of Chemoepitaxy of PMMA-b-P[MA C6 Azobutyl] with L₀ 23 nm (EX. 17, Mn 35 kDa), 1 wt. % 190° C. 1 hr over xPMMA of pitch 112 nm, width 26 nm.

### SUMMARY

This disclosed and claimed subject matter relates to block copolymers with a high Flory Huggins interaction parameter (χ) (a.k.a Chi) based on liquid crystals (LC-BCP) for semiconductor patterning. At certain conditions, the LC-BCP that are described here give vertical lamellar structures directly on Si substates. LC-BCPs have the advantage of being easily alignable into defect free structures without the need of neutral layers (NLD) or topcoats. Further, the high interaction parameter (χ) enables formation of small and large pitches, and formation of thicker ordered copolymer films, which results in an easier etch process and promises to meet industry requirements.

The problem to be solved is the need to pattern integrated circuits with single nanometer feature pitches, by a method that has low defectivity, and does not require excessive steps, fab space, materials, tools, process time, cost, etc. Since multiple patterning and EUV lithography do not meet these requirements, a new method is required as an alternative or complement.

Some low (χ) BCPs (such as PS-PMMA) have been implemented to complement multiple patterning and EUV by DSA, however a set of problems remains:

A neutral layer (underlayer) or topcoat is generally required to obtain standing lamella for commercial (non liquid crystal) BCPs. However, this neutral layer eventually increases defectivity of the pattern transfer during the etch step, in addition to being an extra process step and material. The ideal polymer for DSA would not require the use of neutral layers.

Low χ BCPs are limited in the minimum pitches they can achieve, since the low dissimilarity of the blocks results in phase separation only at higher molecular weights. The ideal polymer for DSA would have higher dissimilarity between the blocks (χ) and would therefore be able to undergo phase separation at low molecular weights, providing lower pitches.

Disclosed herein are novel block copolymer with pendant liquid crystal (LC) moieties which can achieve nanometer sized pitches without the use of a neutral layer with the potential of being able to achieve single digit nanometer sized pitch. Such material may be used as a complement to conventional patterning lithography these types of pitches, without the use of a neutral layer and the processing time and steps needed for creating such neutral layers and the increased defectivity that these extra steps would impart.

Demonstrated are working examples synthetic methods for the synthesis of novel LC-BCP polymerization, where the polymer has the structure PMMA-b-P[MA-Cx-Azobutyl](x=6, 8, 11); which is defined as follows: (PMMA=poly(methyl methacrylate) block segment; P[MA-Cx-Azobutyl]=methacrylate (MA) block segment with attached LC moiety (Cx-Azobutyl); Cx=alkylene spacer between MA carboxylate oxygen and azobutyl moiety, with x carbons in chain linking MA to Azobutyl moiety; Azobutyl moiety=(E)-4-((4-butylphenyl)diazenyl)phenoxy which is attached to the other end of the Cx linking group.

These working synthesis examples include a method for industry-appropriate anionic polymerization. These novel block copolymer structure need to include hydrophobic end group (LC capping group) on the LC pendant moiety which is a linear alkyl with 3 to 8 carbons (C-3 to C-8) (e.g., butyl in the working examples).

These novel block copolymers were able to engender as annealed films on a substrate self-assembled patterns having pitches with a range of 17-73 nm, without the use of an underlayer, and end group examination.

Further, the working examples were able to affect as polymer films DSA graphoepitaxy and also chemoepitaxy on prepatterned substrates.

Experiments on the working examples showed good etch selectivity between the PMMA and P[MA-Cx-Azobutyl]blocks as demonstrated by experiments done with homopolymer and also when etching self-assembled films of the novel block copolymers on SiOx substrate.

The basic approach described herein for these novel block copolymer architectures suitable for use for DSA on substrates without the use of a neutral layer is also supplemented with prophetic examples which are natural extensions of the working examples.
The synthetic methods used for polymerization of the working examples PMMA-b-P[MA-Cx-Azobutyl](x=6, 8, 11) can be used with x=3, 5, 7, 9, 10, 12 and 13 and also with LC capping groups other than butyl (C-4) (a.k.a. C-3, C-5 to C-8) to affect standing lamella of said polymers with pitches as small as 5 nm, without the use of neutral underlayers. Multi-pitch DSA using said prophetic examples, based on initial results with PMMA-b- is expected based on initial results with the working examples.
Especially low defectivity for DSA processing using these novel polymer architectures is expected because of not requiring a neutral layer, for either graphoepitaxy or chemoepitaxy as shown by the working examples this would reduce the number of steps because processing to introduce neutral layers would and be required and this in turn would improve throughput of IC manufacturing using such processes.

Specifically, the novel polymer architectures are AB block copolymer, comprising a first block A of structure (I) and a second block B of structure (II), wherein R and R₁ are individually selected from a C-1 to C-4 alkyl, n is the number of repeat units in structure (I), m is the number of repeat units in structure (II). and the mole % of repeat units of structure (I) ranges from about 35 mole % to about 94 mole %, and the mole % of repeat units of structure (II) ranges from about 6 mole % to about 65 mole % of the total moles of repeat units of structures (I) and (II), and the sum of the mole % of repeat units of structure (I) and (II) equals 100 mole %.

Further, in this polymer R₂ is selected from a C-1 to C-11 alkyl, L is a C-5 to C-12 linear alkylene, and R₃ is selected from a C-3 to C-8 linear alkyl, and R′ is H or a C-3 to C-8 linear alkyl, and further wherein said block copolymer has a polydispersity of 1 to about 1.31.

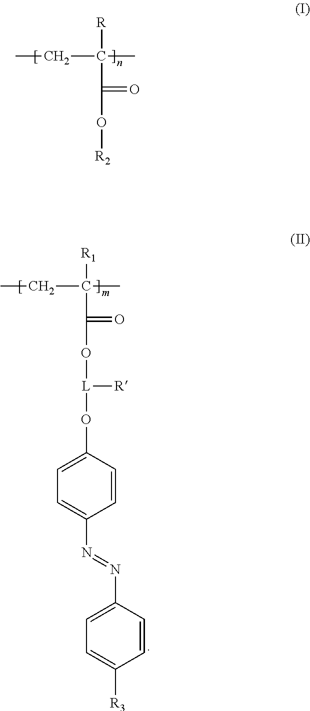

Another aspect of the disclosed and claimed subject matter is compositions comprising said block copolymer and an organic spin casting solvent.

A further aspect of this the disclosed and claimed subject matter is processes of using said composition and/or block copolymer for self-assembly and directed self-assembly lithographic processing.

### DETAILED DESCRIPTION

It is to be understood that both the foregoing general description and the following detailed description are illustrative and explanatory and are not restrictive of the subject matter as claimed. In this application, the use of the singular includes the plural, the word “a” or “an” means “at least one,” and the use of “or” means “and/or,” unless specifically stated otherwise. Furthermore, the use of the term “including,” as well as other forms such as “includes” and “included,” is not limiting. Also, terms such as “element” or “component” encompass both elements and components comprising one unit and elements or components that comprise more than one unit, unless specifically stated otherwise. As used herein, the conjunction “and” is intended to be inclusive and the conjunction “or” is not intended to be exclusive unless otherwise indicated. For example, the phrase “or, alternatively” is intended to be exclusive. As used herein, the term “and/or” refers to any combination of the foregoing elements including using a single element.

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that one or more of the incorporated literature references and similar materials defines a term in a manner that contradicts the definition of that term in this application, this application controls.

Unless otherwise indicated, “alkyl” refers to hydrocarbon groups which can be linear, branched (e.g., methyl, ethyl, propyl, isopropyl, tert-butyl and the like) or cyclic (e.g., cyclohexyl, cyclopropyl, cyclopentyl and the like) multicyclic (e.g., norbornyl, adamantly and the like). These alkyl moieties may be substituted or unsubstituted as described below. The term “alkyl” refers to such moieties with C-1 to C-8 carbons. It is understood that for structural reasons linear alkyls start with C-1, while branched alkyls and cyclic alkyls start with C-3 and multicyclic alkyls start with C-5. Moreover, it is further understood that moieties derived from alkyls described below, such as alkyloxy (alkoxy), have the same carbon number ranges unless otherwise indicated. The same criteria apply to the designation C-1 to C-4 alkyl. If the length of the alkyl group is specified as other than described above, the above-described definition of alkyl still stands with respect to it encompassing all types of alkyl moieties as described above and that the structural consideration with regards to minimum number of carbons for a given type of alkyl group still apply.

Alkyloxy (a.k.a. Alkoxy) refers to an alkyl group on which is attached through an oxy (—O—) moiety (e.g., methoxy, ethoxy, propoxy, butoxy, 1,2-isopropoxy, cyclopentyloxy cyclohexyloxy and the like). These alkyloxy moieties may be substituted or unsubstituted as described below. The criteria for establishing the nature of the alkyl in C-1 to C-8 alkoxy or C-1 to C-4 alkoxy are the same as previously described for alkyl moieties.

Halo or halide refers to a halogen, F, Cl, Br or I which is linked by one bond to an organic moiety.

Haloalkyl refers to a linear, cyclic or branched saturated alkyl group such as defined above in which at least one of the hydrogens has been replaced by a halide selected from the group of F, Cl, Br, I or mixture of these if more than one halo moiety is present. Fluoroalkyls are a specific subgroup of these moieties.

The term “alkylene”, unless otherwise indicated refers to hydrocarbon groups which can be a linear, branched or cyclic which has two or more attachment points (e.g., of two attachment points: methylene, ethylene, 1,2-isopropylene, a 1,4-cyclohexylene and the like; of three attachment points 1,1,1-subsituted methane,1,1,2-subsituted ethane, 1,2,4-subsituted cyclohexane and the like). Here again, when designating a possible range of carbons, such as C-1 to C-20, as a non-limiting example, this range encompasses linear alkylenes starting with C-1 but only designates branched alkylenes, or cycloalkylene starting with C-3. These alkylene moieties may be substituted or unsubstituted as described below. The term linear alkylene, refers to a linear alkylene moiety with two attachment points, which is unsubstituted, unless specified otherwise. For example, L as described herein is a C-5 to C-12 unsubstituted linear alkylene when R′ is H; however, when R′ is a C-3 to C-8 linear alkyl then L is a linear alkylene with a R′ linear alkyl substituent.

The term “aryl” or “aromatic groups” refers to such groups which contain 6 to 24 carbon atoms including phenyl, tolyl, xylyl, naphthyl, anthracyl, biphenyls, bis-phenyls, tris-phenyls and the like. These aryl groups may further be substituted with any of the appropriate substituents, e.g., alkyl, alkoxy, acyl or aryl groups mentioned hereinabove.

Unless otherwise indicated in the text, the term “substituted” when referring to an aryl, alkyl, alkyloxy, fluoroalkyl, fluoroalkyloxy, fused aromatic ring, arene, heteroarene refers to one of these moieties which also contain one or more substituents, selected from the group of unsubstituted alkyl, substituted alkyl, unsubstituted aryl, alkyloxyaryl (alkyl-O-aryl-), dialkyloxyaryl ((alkyl-O-)₂-aryl), haloaryl, alkyloxy, alkylaryl, haloalkyl, halide, hydroxyl, cyano, nitro, acetyl, alkylcarbonyl, formyl, ethenyl (CH₂═CH—), phenylethenyl (Ph-CH═CH—), arylethenyl (Aryl-CH═CH), and substituents comprising ethenylenearylene moieties (e.g., Ar(—CH═CH—Ar—)_{z} where z is 1-3. Specific, non-limiting examples of substituted aryl and substituted aryl ethenyl substituent are as follows where [symbol] represents the point of attachment:

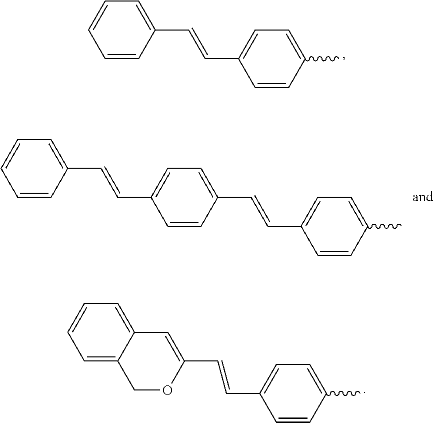

### Inventive Polymers

One aspect of the disclosed and claimed subject matter is a block copolymer, which is an AB diblock copolymer with a first block A of structure (I) and a second block B of structure (II), wherein R and R₁ are individually selected from a C-1 to C-4 alkyl, n is the number of repeat units in structure (I), m is the number of repeat units in structure (II), and the mole % of repeat units of structure (I) ranges from about 35 mole % to about 94 mole %, and the mole % of repeat units of structure (II) ranges from about 6 mole % to about 65 mole % of the total moles of repeat units of structures (I) and (II), and the sum of the mole % of repeat units of structure (I) and (II) equals 100 mole %.

Further, R₂ is selected from a C-1 to C-11 alkyl, L is a C-5 to C-12 linear alkylene, and R₃ is selected from a C-3 to C-8 linear alkyl, and R′ is H or a C-3 to C-8 linear alkyl, and further wherein said block copolymer has a polydispersity of 1 to about 1.31.

In another aspect of these embodiment R₂ is selected from a C-1 to C-10 alkyl. In another aspect of these embodiments, R₂ is a C-1 to C-9 alkyl. In another aspect of these embodiments, R₂ is a C-1 to C-8 alkyl.

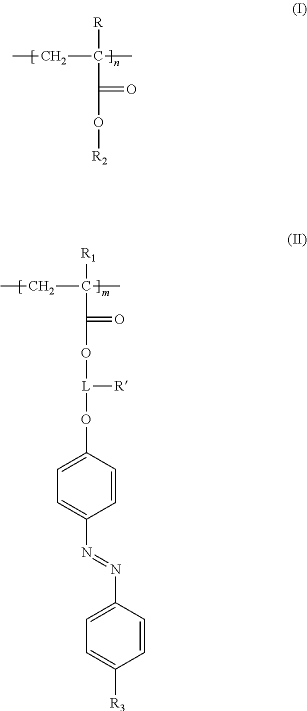

In one aspect of the disclosed and claimed subject matter, said block copolymer is one wherein R′ is H. In another aspect, said block copolymer is one wherein R′ is a C-3 to C-8 linear alkyl.

In one aspect of the disclosed and claimed subject matter said block copolymer, as described herein, is made by anionic or RAFT polymerization.

In another aspect of this embodiment said block copolymer, as described herein, is made by anionic polymerization.

In one aspect, said copolymer is essentially free of metal contaminants such as Aluminum, Calcium, Chromium, Copper, Iron, Magnesium, Manganese, Nickel, Potassium, Sodium, Zinc, Tin, Cadmium, Cobalt Germanium, Lead, Lithium, Silver, and Titanium, where these are metals are individually present at level of less than 2.5 ppb in a solution of these polymers in PGMEA. In one aspect of the disclosed and claimed subject matter the individual level of Calcium, Copper, Potassium, Sodium, and Lithium are less than 0.4 ppb.

In another aspect of the disclosed and claimed subject matter the block copolymer has a polydispersity ranging from 1 to about 1.13. In another aspect of this embodiment the polydispersity ranges from 1 to about 1.10. In yet another aspect of this embodiment said polydispersity ranges from 1 to about 1.05. In yet another aspect of this embodiment said polydispersity ranges from 1 to about 1.02. In still another aspect of this embodiment said polydispersity ranges from 1 to about 1.01.

In another aspect of the disclosed and claimed subject matter the block copolymer has an Mₙ (number average molecular weight) ranging from about 8 kilo-Daltons (kDa) to about 200 kDa. In another aspect of this embodiment Mₙ ranges from about 8 kDa to about 120 kDa. In another aspect of this embodiment Mₙ ranges from about 20 kDa to about 170 kDa. In yet another aspect of this embodiment it ranges from about 37 kDA to about 108 kDA. In another aspect of this embodiment, when said polymer is made by RAFT polymerization the preferred range is from about 8 kDa to about 40 KDa.

In another aspect of this embodiment, it has an Mₙ ranging from about 8 kDa to about 25 kDa.

In another aspect of the disclosed and claimed subject matter the block copolymer it is made by RAFT polymerization it has structure (III), wherein Rr₁, is a C-1 to C-8 alkyl, Rr₂ is a C-1 to C-8 alkyl, and Rr is a cyano moiety (—CN) or a carbonylalkyl moiety (—C(═O)—Ri), wherein Ri is a C-1 to C-8 alkyl or an aryl moiety, and Rr₃ is an unsubstituted or substituted aryl moiety. In one aspect of this embodiment, R′ is H. In another aspect of these embodiments, R′ is a C-3 to C-8 linear alkyl.

In another aspect of these embodiments, R is a C-1 to C-2 alkyl. In another aspect of these embodiments, R is methyl. In another aspect of these embodiments, R₁ is a C-1 to C-2 alkyl. In another aspect of these embodiments R₁ is methyl. In another aspect of these embodiments, R₂ is a C-1 to C-10 alkyl. In another aspect of these embodiments, R₂ is a C-1 to C-9 alkyl. In another aspect of these embodiments, R₂ is a C-1 to C-8 alkyl. In another aspect of these embodiments, R₂ is a C-1 to C-7 alkyl. In another aspect of these embodiments, R₂ is a C-1 to C-6 alkyl. In another aspect of these embodiments, R₂ is a C-1 to C-5 alkyl. In another aspect of these embodiments, R₂ is a C-1 to C-4 alkyl. In another aspect of these embodiments, R₂ is a C-1 to C-3 alkyl. In another aspect of these embodiments, R₂ is a C-1 to C-2 alkyl. In another aspect of these embodiments, R₂ is methyl.

In one aspect of the disclosed and claimed subject matter the block copolymer of structure (III) has structure (IIIa).

In another aspect of the disclosed and claimed subject matter the block copolymers of structures (III) or (IIIa) have structure (IIIa-1).

In more specific aspect of structures (III) and (IIIa), R′ is hydrogen and the inventive block copolymer described herein is one wherein L is C-5 to C-12 unsubstituted linear alkylene unsubstituted and have the more specific structures (III-1), (IIIa-2) and (IIIa-3).

In one aspect of structures (III), (IIIa), (III-1), (IIIa-2) and (IIIa-3), R₃ is a C-3 to C-8 alkyl.

In another aspect R₃ is 1-propyl. In another aspect R₃ is 1-butyl. In another aspect R₃ is 1-pentanyl.

In another aspect R₃ is 1-hexanyl. In another aspect R₃ is 1-heptanyl. In another aspect R₃ is 1-octanyl. In another aspect of these embodiments, L is a C-5 linear alkylene. In another aspect of these embodiments, L is a C-6 linear alkylene. In another aspect of these embodiments, L is a C-7 linear alkylene. In another aspect of these embodiments, L is a C-8 linear alkylene. In another aspect of these embodiments, L is a C-9 linear alkylene. In another aspect of these embodiments, L is a C-10 linear alkylene. In another aspect of these embodiments, L is a C-11 linear alkylene. In another aspect of these embodiments, L is a C-12 linear alkylene. In another aspect of these embodiments, Rr₃ is an unsubstituted aryl. In another aspect of these embodiments, Rr₃ is a substituted aryl. In another aspect of these embodiments, Rr₂ is methyl and Rr₁ is butyl. In another more specific aspect of structures (III) and (IIIa), R′ is H. In another more specific aspect of structures (III) and (IIIa), R′ is a C-3 to C-8 linear alkyl.

In a more detailed aspect of structures (III) and (IIIa), they respectively have structures (IIIb), or (IIIc), wherein n′ and n″ are integers ranging independently from 0 to 11 and further where the sum of n′ and n″ ranges from 4 to 11. A more specific aspect of this embodiment is structure (IIIc-1). In another aspect of these embodiments, n′ is 0 and n″ is 4. In another aspect of these embodiments, n′ is 0 and n″ is 5. In another aspect of these embodiments, n′ is 0 and n″ is 6. In another aspect of these embodiments, n′ is 0 and n″ is 7. In another aspect of these embodiments, n′ is 0 and n″ is 8. In another aspect of these embodiments, n′ is 0 and n″ is 9. In another aspect of these embodiments, n′ is 0 and n″ is 10. In another aspect of these embodiments, n′ is 0 and n″ is 11. In another aspect of these embodiments, n′ is 1 and n″ is 3. In another aspect of these embodiments, n′ is 1 and n″ is 4. In another aspect of these embodiments, n′ is 1 and n″ is 5. In another aspect of these embodiments, n′ is 1 and n″ is 6. In another aspect of these embodiments, n′ is 1 and n″ is 7. In another aspect of these embodiments, n′ is 1 and n″ is 8. In another aspect of these embodiments, n′ is 1 and n″ is 9. In another aspect of these embodiments, n′ is 1 and n″ is 10. In another aspect of these embodiments, n′ is 2 and n″ is 2. In another aspect of these embodiments, n′ is 2 and n″ is 3. In another aspect of these embodiments, n′ is 2 and n″ is 4. In another aspect of these embodiments, n′ is 2 and n″ is 5. In another aspect of these embodiments, n′ is 2 and n″ is 6. In another aspect of these embodiments, n′ is 2 and n″ is 7. In another aspect of these embodiments, n′ is 2 and n″ is 8. In another aspect of these embodiments, n′ is 2 and n″ is 9. In another aspect of these embodiments, n′ is 3 and n″ is 1. In another aspect of these embodiments, n′ is 3 and n″ is 2. In another aspect of these embodiments, n′ is 3 and n″ is 3. In another aspect of these embodiments, n′ is 3 and n″ is 4. In another aspect of these embodiments, n′ is 3 and n″ is 5. In another aspect of these embodiments, n′ is 3 and n″ is 6. In another aspect of these embodiments, n′ is 3 and n″ is 7. In another aspect of these embodiments, n′ is 3 and n″ is 8. In another aspect of these embodiments, n′ is 4 and n″ is 0. In another aspect of these embodiments, n′ is 4 and n″ is 1. In another aspect of these embodiments, n′ is 4 and n″ is 2. In another aspect of these embodiments, n′ is 4 and n″ is 3. n′ is 4 and n″ is 4. In another aspect of these embodiments, n′ is 4 and n″ is 5. In another aspect of these embodiments, n′ is 4 and n″ is 6. In another aspect of these embodiments, n′ is 4 and n″ is 7. In another aspect of these embodiments, n′ is 5 and n″ is 0. In another aspect of these embodiments, n′ is 5 and n″ is 1. In another aspect of these embodiments, n′ is 5 and n″ is 2. In another aspect of these embodiments, n′ is 5 and n″ is 3. In another aspect of these embodiments, n′ is 5 and n″ is 4. In another aspect of these embodiments, n′ is 5 and n″ is 5. In another aspect of these embodiments, n′ is 5 and n″ is 6. In another aspect of these embodiments, n′ is 6 and n″ is 0. In another aspect of these embodiments, n′ is 6 and n″ is 1. In another aspect of these embodiments, n′ is 6 and n″ is 2. In another aspect of these embodiments, n′ is 6 and n″ is 3. In another aspect of these embodiments, n′ is 6 and n″ is 4. In another aspect of these embodiments, n′ is 6 and n″ is 5. In another aspect of these embodiments, n′ is 7 and n″ is 0. n′ is 7 and n″ is 1. In another aspect of these embodiments, n′ is 7 and n″ is 2. In another aspect of these embodiments, n′ is 7 and n″ is 3. In another aspect of these embodiments, n′ is 7 and n″ is 4. n′ is 8 and n″ is 0. In another aspect of these embodiments, n′ is 8 and n″ is 1. In another aspect of these embodiments, n′ is 8 and n″ is 2. In another aspect of these embodiments, n′ is 8 and n″ is 3. In another aspect of these embodiments, n′ is 9 and n″ is 0. In another aspect of these embodiments, n′ is 9 and n″ is 1. In another aspect of these embodiments, n′ is 9 and n″ is 2. In another aspect of these embodiments, n′ is 10 and n″ is 0. In another aspect of these embodiments, n′ is 10 and n″ is 1. In another aspect of these embodiments, n′ is 11 and n″ is 0. In another aspect of these embodiments R₃ is a C-3 to C-8 alkyl. In another aspect R₃ is 1-propyl. In another aspect R₃ is 1-butyl. In another aspect R₃ is 1-pentanyl. In another aspect R₃ is 1-hexanyl. In another aspect R₃ is 1-heptanyl. In another aspect R₃ is 1-octanyl. In another aspect of these embodiments, L is a C-5 linear alkylene. In another aspect of these embodiments, L is a C-6 linear alkylene. In another aspect of these embodiments, L is a C-7 linear alkylene. In another aspect of these embodiments, L is a C-8 linear alkylene. In another aspect of these embodiments, L is a C-9 linear alkylene. In another aspect of these embodiments, L is a C-10 linear alkylene. In another aspect of these embodiments, L is a C-11 linear alkylene. In another aspect of these embodiments, L is a C-12 linear alkylene. In another aspect of these embodiments, Rr₃ is an unsubstituted aryl. In another aspect of these embodiments, Rr₃ is a substituted aryl. In another aspect of these embodiments, Rr₂ is methyl and Rr₁ is butyl.

In another aspect of the disclosed and claimed subject matter the block copolymer is made by RAFT polymerization, the —S—(C═S)—Rr₃ end group is removed and replaced by hydrogen and have structures (III′), (IIIa′), (IIIa-1′), (IIIa-2′), (IIIa-3′), (IIb′), (IIc′), or (IIIc-1′).

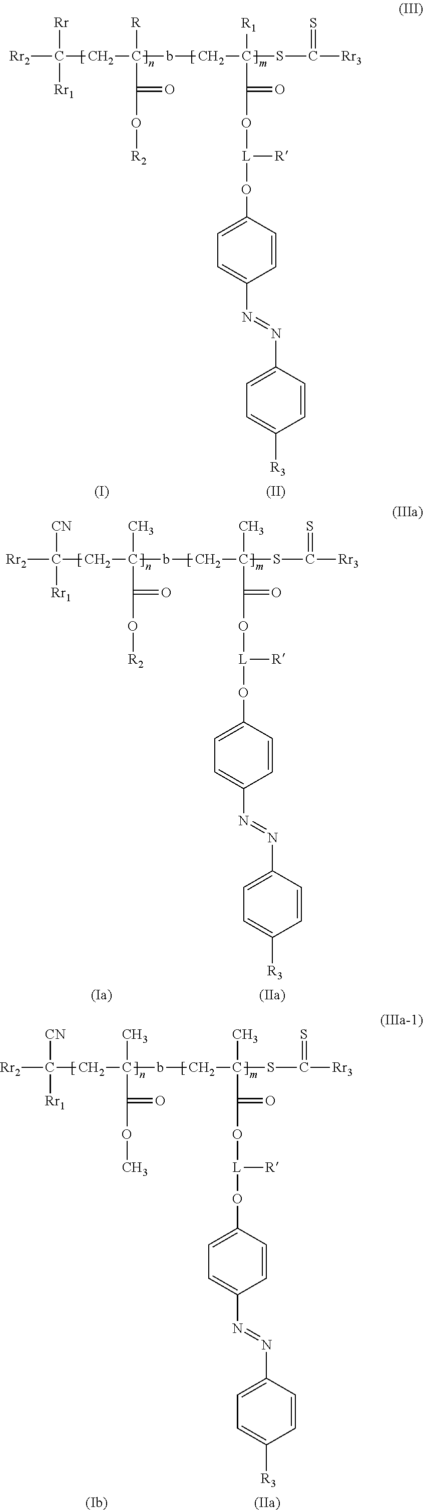

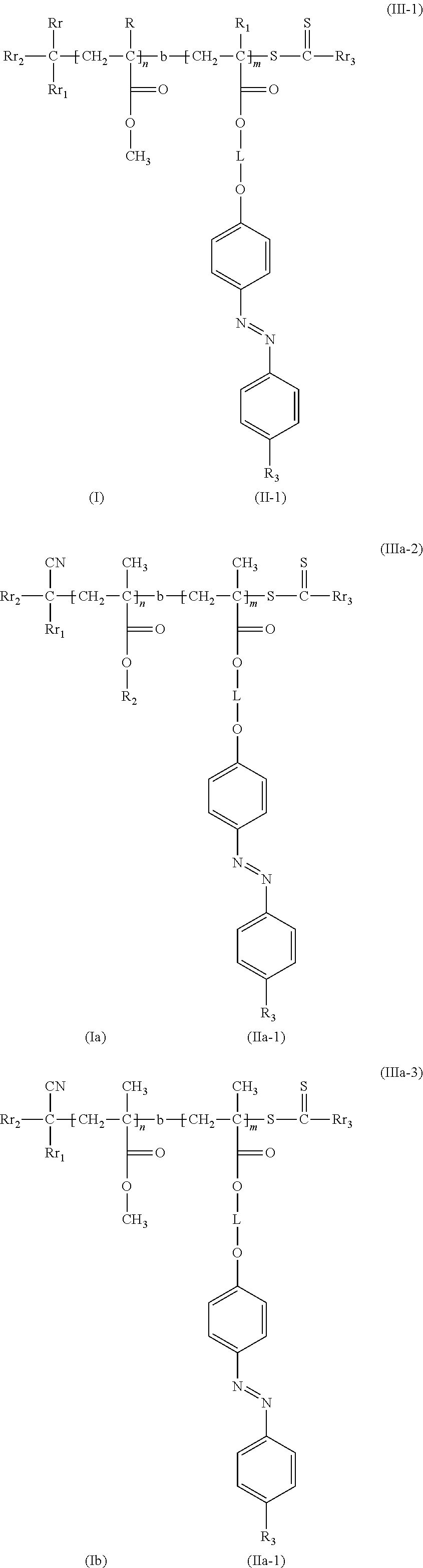

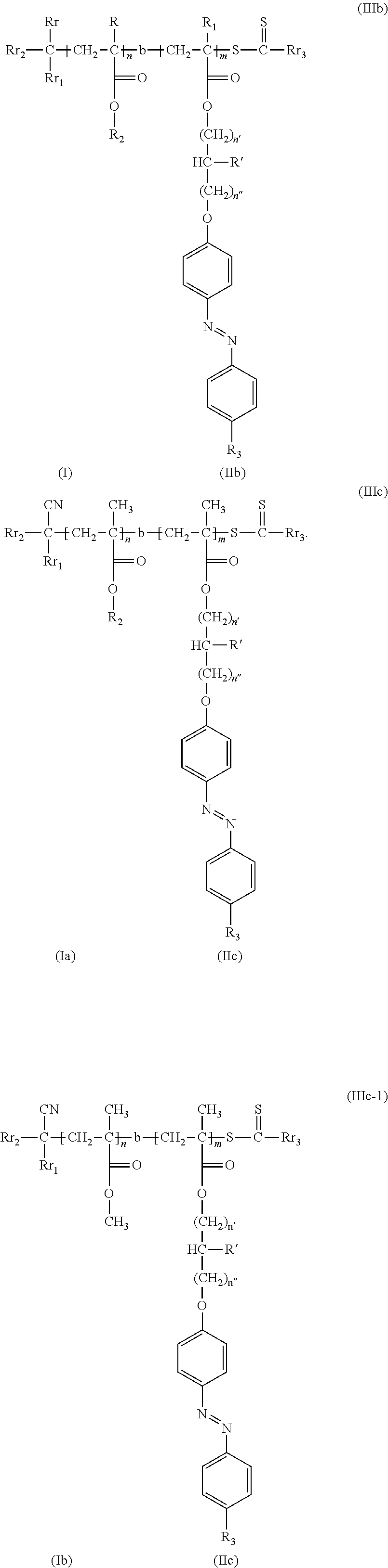

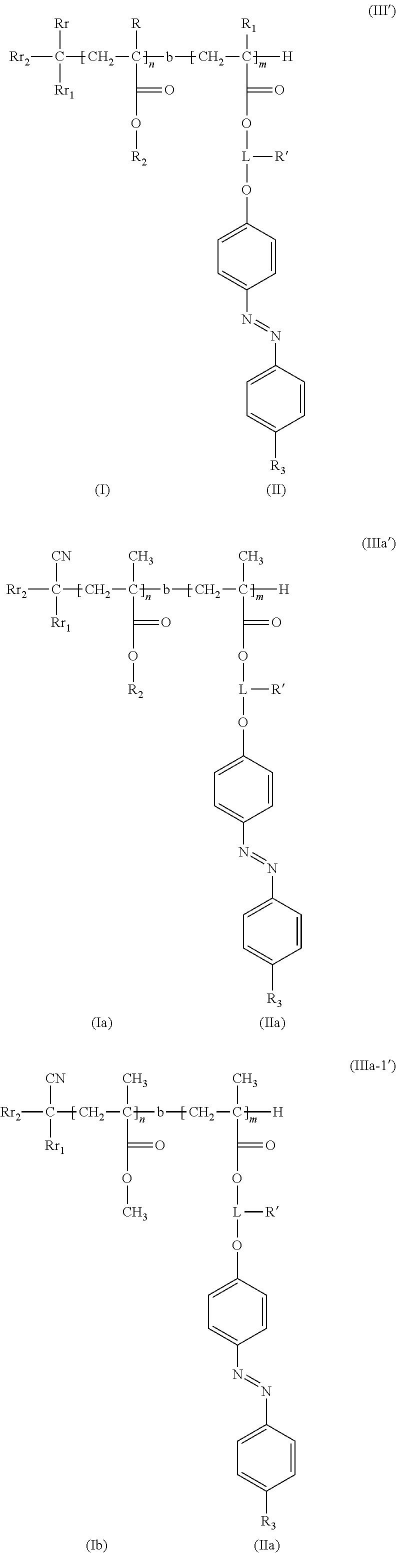

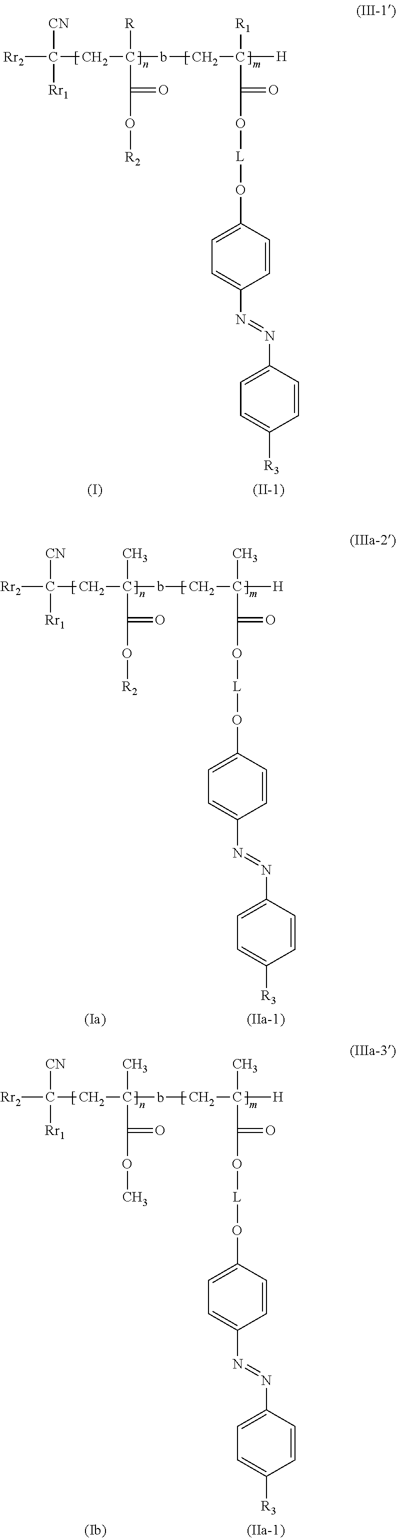

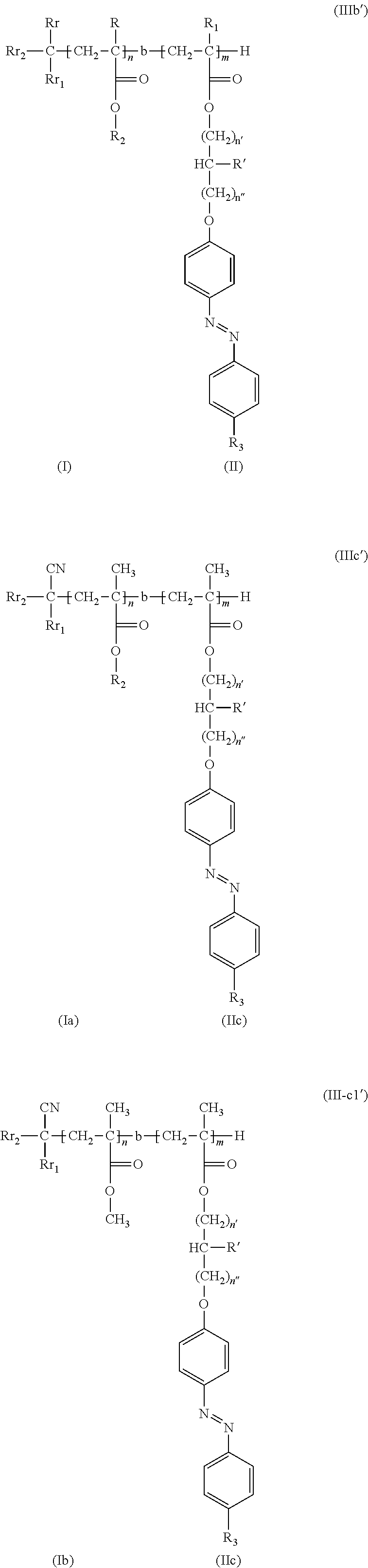

In another aspect of the disclosed and claimed subject matter the block copolymer is made by anionic polymerization. In one aspect of this embodiment, it has structure (IV), wherein Rₑ is a C-1 to C-8 alkyl, Rm and Rm₁ are individually selected from H, a C-1 to C-8 alkyl, a C-1 to C-8 alkoxy. In another aspect of this embodiment, wherein R is a C-1 to C-2 alkyl. In another aspect of this embodiment, R is methyl. In another aspect of this embodiment, R₁ is a C-1 to C-2 alkyl. In another aspect of this embodiment, R₁ is methyl. In another aspect of this embodiment, R₂ is a C-1 to C-10 alkyl. In another aspect of this embodiment, R₂ is a C-1 to C-9 alkyl. In another aspect of this embodiment, R₂ is a C-1 to C-8 alkyl. In another aspect of this embodiment, R₂ is a C-1 to C-7 alkyl. In another aspect of this embodiment, R₂ is a C-1 to C-6 alkyl. In another aspect of this embodiment, R₂ is a C-1 to C-5 alkyl. In another aspect of this embodiment, R₂ is a C-1 to C-4 alkyl. In another aspect of this embodiment, R₂ is a C-1 to C-3 alkyl. In another aspect of this embodiment, R₂ is a C-1 to C-2 alkyl. In one aspect of this embodiment, R′ is H. In another aspect of this embodiment, R′ is a C-3 to C-8 linear alkyl. In another aspect of these embodiments, R is a C-1 to C-2 alkyl. In another aspect of these embodiments, R is methyl. In another aspect of these embodiments, R₁ is a C-1 to C-2 alkyl. In another aspect of these embodiments R₁ is methyl. In another aspect of these embodiments, R₂ is a C-1 to C-4 alkyl. In another aspect of these embodiments, R₂ is a C-1 to C-2 alkyl. In another aspect of these embodiments, R₂ is methyl. In another aspect of these embodiments, R₃ is a C-3 to C-7 linear alkyl. In another aspect of these embodiments, R₃ is a C-3 to C-6 linear alkyl. In another aspect of these embodiments, R₃ is a C-3 to C-5 linear alkyl. In another aspect of these embodiments, R₃ is n-butyl. In another aspect of these embodiments, L is a C-5 linear alkylene. In another aspect of these embodiments, L is a C-6 linear alkylene. In another aspect of these embodiments, L is a C-7 linear alkylene. In another aspect of these embodiments, L is a C-8 linear alkylene. In another aspect of these embodiments, L is a C-9 linear alkylene. In another aspect of these embodiments, L is a C-10 linear alkylene. In another aspect of these embodiments, L is a C-11 linear alkylene. In another aspect of these embodiments, L is a C-12 linear alkylene.

In another aspect of these embodiments, said block copolymer has the more specific structure (IVa) or (IVa-1). In one aspect of these embodiments R′ is H and L is an unsubstituted C-5 to C-12 alkylene and the polymers made by anionic polymerization have the corresponding structures (IV′), (IVa′) or (IVa-1′). In one aspect of these embodiments, R₃ is a C-3 to C-8 alkyl. In another aspect of these embodiments, R₃ is 1-propyl. In another aspect of these embodiments, R₃ is 1-butyl. In another aspect of these embodiments, R₃ is 1-pentanyl. In another aspect of these embodiments, R₃ is 1-hexanyl. In another aspect of these embodiments, wherein R₃ is 1-heptanyl. In another aspect of these embodiments, R₃ is 1-octanyl. In another aspect of these embodiments, L is a C-5 linear alkylene. In another aspect of these embodiments, L is a C-6 linear alkylene. In another aspect of these embodiments, L is a C-7 linear alkylene. In another aspect of these embodiments, L is a C-8 linear alkylene. In another aspect of these embodiments, L is a C-9 linear alkylene. In another aspect of these embodiments, L is a C-10 linear alkylene. In another aspect of these embodiments, L is a C-11 linear alkylene. In another aspect of these embodiments, L is a C-12 linear alkylene.

In another aspect of the block copolymer of structure (IV), (IVa) and (IVa-1) R′ is a C-3 to C-8 linear alkyl. In one aspect R′ is a C-4 to C-8 linear alkyl. In another aspect R′ is a C-4 to C-8 linear alkyl. In another aspect R′ is a C-5 to C-8 linear alkyl. In another aspect R′ is a C-5 to C-8 linear alkyl. In another aspect R′ is a C-6 to C-8 linear alkyl. In another aspect R′ is a C-7 to C-8 linear alkyl. In another aspect R′ is a C-7 linear alkyl. In another aspect R′ is a C-8 linear alkyl.

In one aspect of this embodiment, the block copolymer of structure (IV) has the more specific structures (IVb) or (IVc), wherein n′ and n″ are integers ranging independently from 0 to 11 and further where the sum of n′ and n″ ranges from 4 to 11. In a more detailed aspect of these structures, they respectively have structures (IVb), or (VIc), wherein n′ and n″ are integers ranging independently from 0 to 11 and further where the sum of n′ and n″ ranges from 4 to 11. A more specific aspect of this embodiment is structure (IVc-1). In another aspect of these embodiments, n′ is 0 and n″ is 4. In another aspect of these embodiments, n′ is 0 and n″ is 5. In another aspect of these embodiments, n′ is 0 and n″ is 6. In another aspect of these embodiments, n′ is 0 and n″ is 7. In another aspect of these embodiments, n′ is 0 and n″ is 8. In another aspect of these embodiments, n′ is 0 and n″ is 9. In another aspect of these embodiments, n′ is 0 and n″ is 10. In another aspect of these embodiments, n′ is 0 and n″ is 11. In another aspect of these embodiments, n′ is 1 and n″ is 3. In another aspect of these embodiments, n′ is 1 and n″ is 4. In another aspect of these embodiments, n′ is 1 and n″ is 5. In another aspect of these embodiments, n′ is 1 and n″ is 6. In another aspect of these embodiments, n′ is 1 and n″ is 7. In another aspect of these embodiments, n′ is 1 and n″ is 8. In another aspect of these embodiments, n′ is 1 and n″ is 9. In another aspect of these embodiments, n′ is 1 and n″ is 10. In another aspect of these embodiments, n′ is 2 and n″ is 2. In another aspect of these embodiments, n′ is 2 and n″ is 3. In another aspect of these embodiments, n′ is 2 and n″ is 4. In another aspect of these embodiments, n′ is 2 and n″ is 5. In another aspect of these embodiments, n′ is 2 and n″ is 6. In another aspect of these embodiments, n′ is 2 and n″ is 7. In another aspect of these embodiments, n′ is 2 and n″ is 8. In another aspect of these embodiments, n′ is 2 and n″ is 9. In another aspect of these embodiments, n′ is 3 and n″ is 1. In another aspect of these embodiments, n′ is 3 and n″ is 2. In another aspect of these embodiments, n′ is 3 and n″ is 3. In another aspect of these embodiments, n′ is 3 and n″ is 4. In another aspect of these embodiments, n′ is 3 and n″ is 5. In another aspect of these embodiments, n′ is 3 and n″ is 6. In another aspect of these embodiments, n′ is 3 and n″ is 7. In another aspect of these embodiments, n′ is 3 and n″ is 8. In another aspect of these embodiments, n′ is 4 and n″ is 0. In another aspect of these embodiments, n′ is 4 and n″ is 1. In another aspect of these embodiments, n′ is 4 and n″ is 2. In another aspect of these embodiments, n′ is 4 and n″ is 3. n′ is 4 and n″ is 4. In another aspect of these embodiments, n′ is 4 and n″ is 5. In another aspect of these embodiments, n′ is 4 and n″ is 6. In another aspect of these embodiments, n′ is 4 and n″ is 7. In another aspect of these embodiments, n′ is 5 and n″ is 0. In another aspect of these embodiments, n′ is 5 and n″ is 1. In another aspect of these embodiments, n′ is 5 and n″ is 2. In another aspect of these embodiments, n′ is 5 and n″ is 3. In another aspect of these embodiments, n′ is 5 and n″ is 4. In another aspect of these embodiments, n′ is 5 and n″ is 5. In another aspect of these embodiments, n′ is 5 and n″ is 6. In another aspect of these embodiments, n′ is 6 and n″ is 0. In another aspect of these embodiments, n′ is 6 and n″ is 1. In another aspect of these embodiments, n′ is 6 and n″ is 2. In another aspect of these embodiments, n′ is 6 and n″ is 3. In another aspect of these embodiments, n′ is 6 and n″ is 4. In another aspect of these embodiments, n′ is 6 and n″ is 5. In another aspect of these embodiments, n′ is 7 and n″ is 0. n′ is 7 and n″ is 1. In another aspect of these embodiments, n′ is 7 and n″ is 2. In another aspect of these embodiments, n′ is 7 and n″ is 3. In another aspect of these embodiments, n′ is 7 and n″ is 4. n′ is 8 and n″ is 0. In another aspect of these embodiments, n′ is 8 and n″ is 1. In another aspect of these embodiments, n′ is 8 and n″ is 2. In another aspect of these embodiments, n′ is 8 and n″ is 3. In another aspect of these embodiments, n′ is 9 and n″ is 0. In another aspect of these embodiments, n′ is 9 and n″ is 1. In another aspect of these embodiments, n′ is 9 and n″ is 2. In another aspect of these embodiments, n′ is 10 and n″ is 0. In another aspect of these embodiments, n′ is 10 and n″ is 1. In another aspect of these embodiments, n′ is 11 and n″ is 0.

In another aspect of the embodiments where said block copolymer has structure (IV), (IVa), (IVa-1), (IV′), (IVa′), (IVa-1′), (IVb) (IVc) or (IVc-1), R₃ is a C-3 to C-7 linear alkyl. In another aspect of these embodiments, R₃ is a C-3 to C-7 linear alkyl. In another aspect of these embodiments, R₃ is a C-3 to C-6 linear alkyl. In another aspect of these embodiments, R₃ is a C-3 to C-5 linear alkyl. In another aspect of these embodiments, R₃ is n-butyl. In another aspect of these embodiments, L is a C-5 linear alkylene. wherein L is a C-6 linear alkylene. In another aspect of these embodiments, L is a C-7 linear alkylene. In another aspect of these embodiments, L is a C-8 linear alkylene. In another aspect of these embodiments, L is a C-9 linear alkylene. In another aspect of these embodiments, L is a C-10 linear alkylene. In another aspect of these embodiments, L is a C-11 linear alkylene. In another aspect of these embodiments, L is a C-12 linear alkylene. In another aspect of these embodiments Rm and Rm₁ are H.

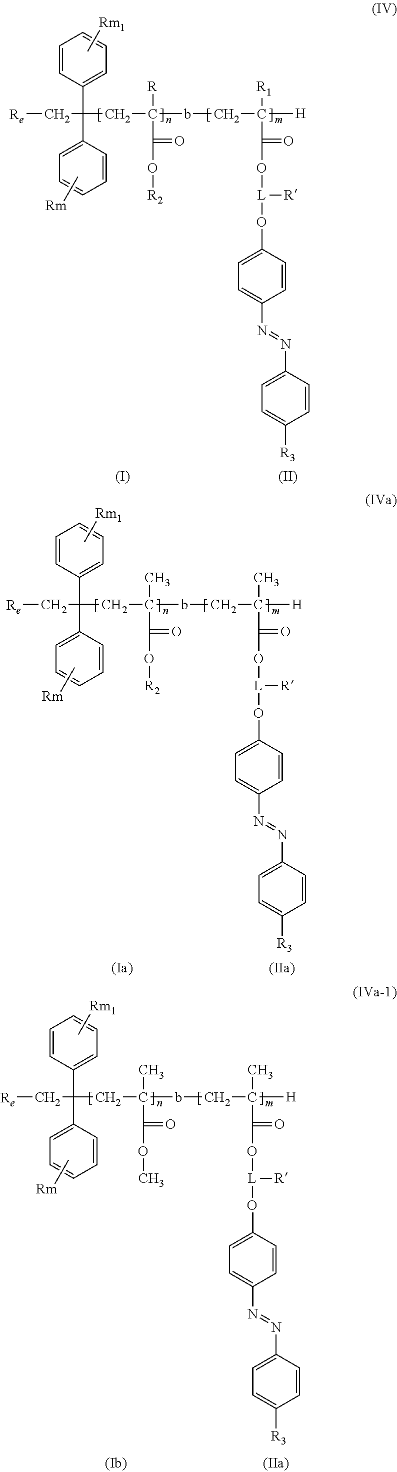

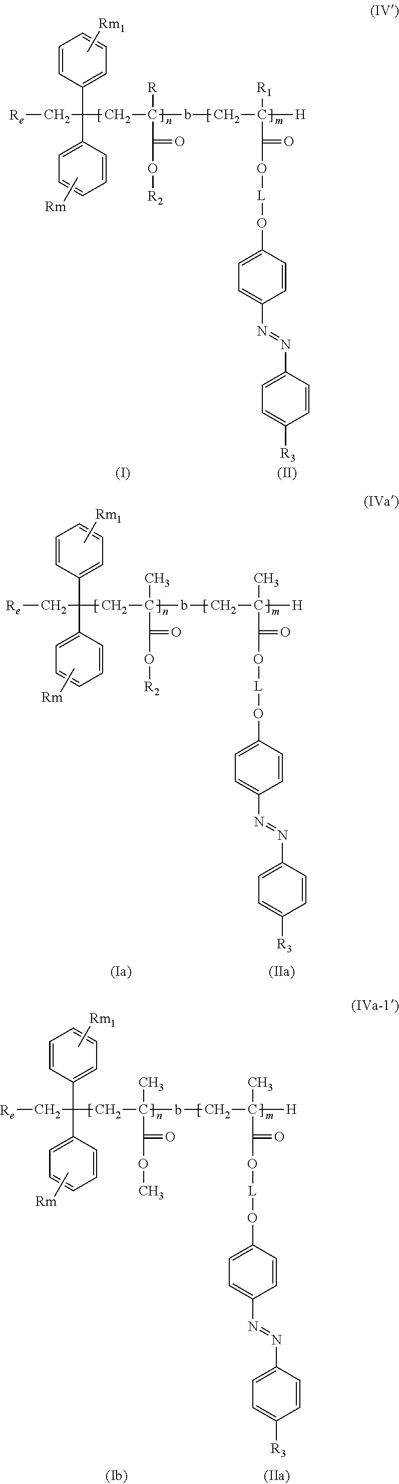

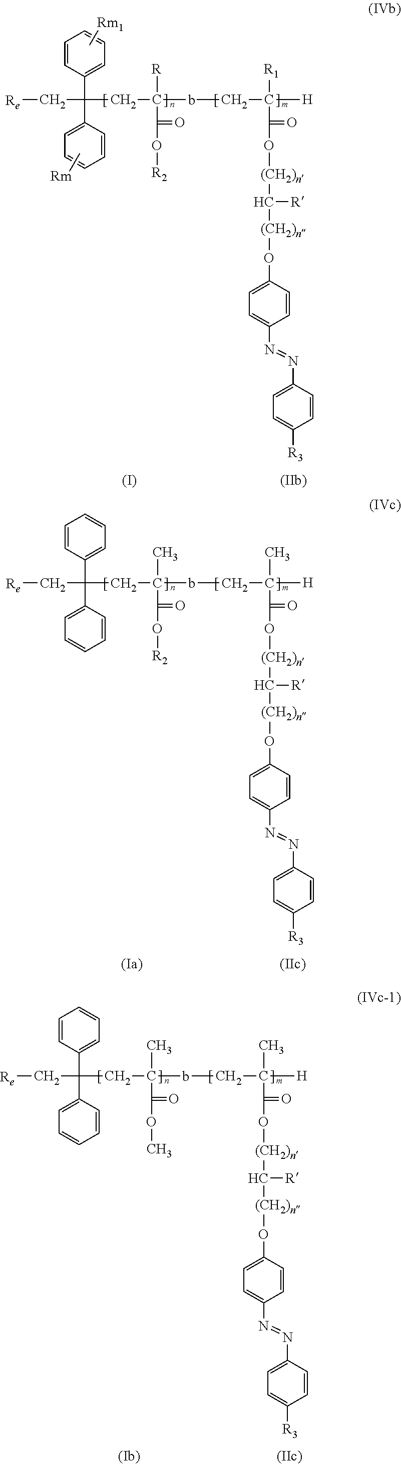

### Inventive Compositions

Another aspect of the disclosed and claimed subject matter is a composition comprising any of the inventive block copolymers described herein and an organic spin casting solvent. Another aspect of the disclosed and claimed subject matter is a composition comprising any of the inventive block copolymers described herein which is made by RAFT polymerization and an organic spin casting solvent. Another aspect of the disclosed and claimed subject matter is a composition comprising any of the inventive block copolymers described herein which is made by anionic polymerization and an organic spin casting solvent.

Another aspect of said invention is novel compositions wherein the concentration of said novel polymers ranges from about 0.2 wt. % to about 2 wt. % of the total weight of said composition including the organic spin casting solvent. In another aspect it ranges from about 0.5 wt. % to about 2 wt. %.

Another aspect of the disclosed and claimed subject matter is a composition of any one of the inventive block copolymers, described herein having structure (III), (IIIa), (IIIa-1), (III-1), (IIIa-2), (IIIa-3), (IIIb), (IIIc), (IIIc-1), (III′), (IIIa′), (IIIa-1′), (III-1′), (IIIa-2′), (IIIa-3′), (IIIb′), (IIIc′), or (IIIc-1′) and an organic spin casting solvent. In one aspect of this embodiment said block copolymer has general structure (III). In another aspect it has structure (IIIa). In another aspect it has structure (IIIa-1). In another aspect it has structure (III-1). In another aspect it has structure (IIIa-2). In another aspect it has structure (IIIa-3). In another aspect it has structure (IIIb). In another aspect it has structure (IIIc). In another aspect it has structure (IIIc-1). In another aspect it has structure (III′).

In another aspect it has structure (IIIa′). In another aspect it has structure (IIIa-1′). In another aspect it has structure (III-1′). In another aspect it has structure (IIIa-2′). In another aspect it has structure (IIIa-3′). In another aspect it has structure (IIb′). In another aspect it has structure (IIIc′). In another aspect it has structure or (IIIc-1′).

Another aspect of the disclosed and claimed subject matter is a composition of any one of the inventive block copolymers, described herein having structure (IV), (IVa), (IVa-1), (IV′), (IVa′), (IVa-1′), (IVb), (IVc), or (IVc-1), and an organic spin casting solvent. In one aspect of this embodiment, it has general structure (IV). In another embodiment is has the more specific structure (IVa). In another aspect it has structure (IVa-1). In another aspect it has structure (IV′). In another aspect it has structure (IVa′). In another aspect it has structure (IVa-1′). In another aspect it has structure (IVb). In another aspect it has structure (IVc). In another aspect it has structure or (IVc-1).

In the above embodiments of the novel compositions, the organic spin casting solvent is one which can dissolve said novel polymers and any other additional optional components as noted above. This organic spin casting solvent may be a single solvent or a mixture of solvents. Suitable solvents are organic solvent which may include, for example, a glycol ether derivative such as ethyl cellosolve, methyl cellosolve, propylene glycol monomethyl ether (PGME), diethylene glycol monomethyl ether, diethylene glycol monoethyl ether, dipropylene glycol dimethyl ether, propylene glycol n-propyl ether, or diethylene glycol dimethyl ether; a glycol ether ester derivative such as ethyl cellosolve acetate, methyl cellosolve acetate, or propylene glycol monomethyl ether acetate (PGMEA); carboxylates such as ethyl acetate, n-butyl acetate and amyl acetate; carboxylates of di-basic acids such as diethyloxylate and diethylmalonate; dicarboxylates of glycols such as ethylene glycol diacetate and propylene glycol diacetate; and hydroxy carboxylates such as methyl lactate, ethyl lactate (EL), ethyl glycolate, and ethyl-3-hydroxy propionate; a ketone ester such as methyl pyruvate or ethyl pyruvate; an alkyloxycarboxylic acid ester such as methyl 3-methoxypropionate, ethyl 3-ethoxypropionate, ethyl 2-hydroxy-2-methylpropionate, or methylethoxypropionate; a ketone derivative such as methyl ethyl ketone, acetyl acetone, cyclopentanone, cyclohexanone or 2-heptanone; a ketone ether derivative such as diacetone alcohol methyl ether; a ketone alcohol derivative such as acetol or diacetone alcohol; a ketal or acetal like 1,3 dioxalane and diethoxypropane; lactones such as butyrolactone; an amide derivative such as dimethylacetamide or dimethylformamide, aromatic solvents such as naptha, xylene, 1,2,4-trimethylbenzene, di-isopropylnaphalene, phenylxylyethane, chlorobenzene, 1,2-dichlorobenzene, toluene or anisole, and mixtures thereof. In one aspect of this embodiment said organic spin casting solvent selected from glycol ether derivative such as ethyl cellosolve, methyl cellosolve, propylene glycol monomethyl ether (PGME), diethylene glycol monomethyl ether, diethylene glycol monoethyl ether, dipropylene glycol dimethyl ether, propylene glycol n-propyl ether, or diethylene glycol dimethyl ether; a glycol ether ester derivative such as ethyl cellosolve acetate, methyl cellosolve acetate, or propylene glycol monomethyl ether acetate (PGMEA) and mixtures thereof; in one aspect of this embodiment it is PGMEA, in another it is a mixture of PGMEA and PGME. In another aspect of this embodiment said organic spin casting solvent is selected from an aromatic solvent such as naptha, xylene, 1,2,4-trimethylbenzene, di-isopropylnaphalene, phenylxylyethane, chlorobenzene, 1,2-dichlorobenzene, toluene or anisole, and mixtures thereof; in one aspect of this embodiment said solvent is toluene.

The novel compositions, in addition to the polymer and the solvent, may contain surfactants as additives to facilitate coating.

### Methods of Using Inventive Compositions.

Another aspect of the disclosed and claimed subject matter is a method of vertically orienting first and second block copolymer domains over an unpatterned substrate using a layer of a block copolymer having a periodicity of L₀ comprising the steps of:
a) forming a coating layer of any one of the copolymer described herein, using a composition of said block copolymer in an organic spin casting solvent, on said unpatterned substrate, which is not a neutral layer, using a composition of this copolymer in an organic spin casting solvent,
b) annealing the layer of the block copolymer to generate a non-zero positive integer number of first and second block copolymer domains, vertically oriented on said unpatterned substrate.

In another aspect of this method said unpatterned substrate is selected from silicon (Si), silicon dioxide (SiOx), silicon nitride (SiN), silicon oxynitride (SiON). In one aspect of this method, said unpatterned substrate is silicon. In another aspect of this method said unpatterned substrate is silicon dioxide. In another aspect of this method, said unpatterned substrate is silicon nitride. In another aspect of this method, said unpatterned substrate is silicon oxynitride.

In another aspect of this method said block copolymer has structure (III), or more specifically structure (IIIa), (IIIa-1), (III-1), (IIIa-2), (IIIa-3), (IIIb), (IIIc), (IIIc-1), (III′), (IIIa′), (IIIa-1′), (III-1′), (IIIa-2′), (IIIa-3′), (IIIb′), (IIIc′), or (IIIc-1′).

In another aspect of this method said block copolymer has structure (IV), or more specifically structure (IVa), (IVa-1), (IV′), (IVa′), (IVa-1′), (IVb), (IVc), or (IVc-1).

Another aspect of the disclosed and claimed subject matter is a method of vertically orienting first and second block copolymer domains over a first patterned substrate where the height of topography of the pattern on the substrate is at least 0.7 times L₀ and aligning the domains with the pattern, using a coating comprising block copolymer having a periodicity of L₀, where further the bottom of the patterned substrate defined by said topography is not as neutral layer surface, comprising the steps of:
a-1) forming a coating layer any one of the block copolymer, described herein, using a composition of said block copolymer in an organic spin casting solvent, on said first topographical substrate, wherein the average thickness of the coating layer of the block copolymer is less than the height of the topography of the first topographical substrate, wherein the block copolymer layer is laterally confined by the topography; and,
b-1) annealing the block copolymer layer to generate first and second block copolymer domains, vertically oriented on said first patterned substrate, and confined within the recessed region.

In another aspect of this method said patterned substrate comprises a pattern of a crosslinked polar polymer on a silicon, silicon dioxide, silicon nitride or silicon oxynitride substrate.

In one aspect of this method, said pattern is on silicon. In another aspect of this method said pattern is on silicon dioxide. In another aspect of this method, said pattern is on silicon nitride. In another aspect of this method, said pattern is on silicon oxynitride.

In another aspect of this method said block copolymer has structure (III), or more specifically structures ((IIIa), (IIIa-1), (III-1), (IIIa-2), (IIIa-3), (IIIb), (IIIc), (IIIc-1), (III′), (IIIa′), (IIIa-1′), (III-1′), (IIIa-2′), (IIIa-3′), (IIIb′), (IIIc′), or (IIIc-1′).

In another aspect of this method said block copolymer has structure (IV), or more specifically structure (IVa), (IVa-1), (IV′), (IVa′), (IVa-1′), (IVb), (IVc), or (IVc-1).

In one aspect of this method said pattern is that of a crosslinked alkyl acrylate or alkyl methacrylate; in a specific embodiment of this aspect said pattern is one of crosslinked poly(methyl methacrylate. One example of a suitable crosslinked poly(methyl methacrylate), are as described in Proc. SPIE 9051, Advances in Patterning Materials and Processes XXXI, 90510K (27 Mar. 2014); doi: 10.1117/12.2048179. More specifically, for this method, suitable patterned layers of poly(methyl methacrylate) may be obtained from a layer of a copolymer of methyl methacrylate and 2-(vinyloxy)ethyl methacrylate (WOI5044215) which may either be crosslinked thermally or with a thermal radical generator, to produce a crosslinked poly(methyl methacrylate) (X-PMMA). This X-PMMA may then then be patterned by overcoating with a photoresist such as AIM5484 JSR iArF photo resist, patterning, pattering said photoresist with radiation such ArF radiation, followed by developing the exposed photoresist film. This forms a patterned photoresist overlaying the X-PMMA which is used as an etch mask to selectively etch away part of X-PMMA layer. The etching process may use a chemical etchant or alternatively a plasma such an oxygen plasma. After this etching pattern transfer the residual patterned photoresist is stripped with a chemical stripper such as MS6800 from Fujifilm forming a patterned X-PMMA. In one aspect of this method, said pattern of a crosslinked polar polymer is formed by patterning with UV radiation a coating of a copolymer of methyl methacrylate and 2-(vinyloxy)ethyl methacrylate on said substrate.

In another aspect of this method said pattern is a line and space (L/S) pattern.

Another aspect of the disclosed and claimed subject matter is a method of vertically orienting, first and second block copolymer domains with a periodicity of L₀ over a second patterned substrate having a topographical pattern with the height of topography larger than 0.7 times L₀ and a pitch P₁ where the pitch P₁ is a non-zero positive integer multiplied by L₀, where further the bottom of the patterned substrate defined by said topography is not a neutral layer surface, and aligning the domains with the pattern comprising the steps of:
a-2) forming a coating layer any one of the block copolymer, described herein, using a composition of said block copolymer in an organic spin casting solvent, on said second patterned substrate, where the thickness of the coating layer of the block copolymer is more than the height of the topography of the second patterned substrate; and,
b-2) annealing the block copolymer layer to generate a non-zero positive integer number of first and second block copolymer domains vertically oriented on said second patterned substrate and aligning them to the second patterned substrate where the sum of vertically oriented domains is equal to or larger than the pitch the P₁ of the topographical pattern.

In another aspect of this method said patterned substrate comprises a pattern of a crosslinked polar polymer on a silicon, silicon dioxide, silicon nitride or silicon oxynitride substrate. Suitable, patterns of a polar polymer may be obtained as described in the prior method.

In one aspect of this method, said pattern is on silicon. In another aspect of this method said pattern is on silicon dioxide. In another aspect of this method, said pattern is on silicon nitride. In another aspect of this method, said pattern is on silicon oxynitride.

In another aspect of this method said block copolymer has structure (III), or more specifically structures (IIIa), (IIIb) or (IIIc).

In another aspect of this method said block copolymer has structure (IV), or more specifically structure (IVa).

In one aspect of this method said pattern is that of a crosslinked alkyl acrylate or alkyl methacrylate; in a specific embodiment of this aspect said pattern of a crosslinked polar polymer is formed by patterning with UV radiation a coating of X-PMMA, as described above. In one aspect of this method, said pattern of a crosslinked polar polymer is formed by patterning with UV radiation a coating of a copolymer of methyl methacrylate and 2-(vinyloxy)ethyl methacrylate on said substrate.

In one aspect of this embodiment X-PMMA is a copolymer of methyl methacrylate and vinyl ether.

In another aspect of this method said pattern is a line and space (L/S) pattern.

Another aspect of the disclosed and claimed subject matter is a method of vertically orienting first and second block copolymer domains over a substrate having a surface chemical prepattern which does not include a neutral layer area, having a pitch P₂, where the pitch P₂ is a non-zero positive integer multiplied by L₀ and aligning the domains comprising the steps of:
a-3) forming a coating layer of one of the block copolymer, described herein, using a composition of said block copolymer in an organic spin casting solvent, on the substrate having a surface chemical prepattern; and,
b-3) annealing the block copolymer layer to generate vertically oriented first and second block copolymer domains aligned with the substrate having a surface chemical prepattern having a pitch P₂.

In another aspect of this method, said surface chemical prepattern comprises both crosslinked polar polymer areas and areas of silicon, silicon dioxide, silicon nitride or silicon oxynitride. In another aspect of this method said patterned substrate comprises a pattern of a crosslinked polar polymer on a silicon, silicon dioxide, silicon nitride or silicon oxynitride substrate.

In one aspect of this method, said pattern is on silicon. In another aspect of this method said pattern is on silicon dioxide. In another aspect of this method, said pattern is on silicon nitride. In another aspect of this method, said pattern is on silicon oxynitride.

In another aspect of this method, said surface chemical prepattern is formed by patterning with UV radiation a coating of a copolymer of methyl methacrylate and 2-(vinyloxy)ethyl methacrylate on said substrate.

In another aspect of this method said block copolymer has structure (III), or more specifically structure(IIIa), (IIIa-1), (III-1), (IIIa-2), (IIIa-3), (IIIb), (IIIc), (IIIc-1), (III′), (IIIa′), (IIIa-1′), (IIIa-2′), (IIIa-3′), (IIIb′), (IIIc′), or (IIIc-1′).

In another aspect of this method said block copolymer has structure (IV), or more specifically structure (IVa), (IVa-1), (IV′), (IVa′), (IVa-1′), (IVb), (IVc), or (IVc-1).

In one aspect of this method said surface chemical prepattern comprises polar brush areas which consist of grafted monolayers of a polar pinning polymer. In one aspect of this embodiment said polar pinning polymer is an alkyl methacrylate with a grafting end group. In one aspect of this embodiment said alkyl methacrylate with a grafting end group. Is one with a narrow polydispersity ranging from 1 to about 1.15. In another aspect of this embodiment said alkyl methacrylate with a grafting group with a narrow polydispersity is methyl methacrylate. In another aspect of this method the chemical prepattern arising from the polar pinning polymer has a thickness ranging from about 3 nm to about 13 nm, in another aspect this chemical prepattern has a thickness of about 3.5 nm to about 12.0 nm, in another aspect it has a thickness of about 4.0 nm to about 11 nm, in another aspect if has a thickness of about 4.5 nm to about 10 nm, in another aspect it has a thickness of about 4.5 nm to about 9 nm, in another aspect if has a thickness of about 4.5 nm to about 8 nm. In another aspect of this method, said surface chemical prepattern is a patterned polar brush formed by first grafting onto a substrate a polar brush layer using a poly(methyl methacrylate) polymer functionalized at one of the polymer chains with a hydroxy group and then forming said chemical and then selectively etching it away using an overlying patterned photoresist as an etch barrier and stripping the photoresist.

In another aspect of this method said surface chemical prepattern is comprises non-polar brush areas which consist of grafted monolayers of a non-polar pinning polymer. In one aspect of this embodiment said non-polar pinning polymer is a styrenic polymer with a grafting end group. This grafting end group is one which has reactivity towards substrates such a SiOx, SiN or SiON and can therefore form a surface which is functionalized with styrenic brush. In one aspect of this embodiment said styrenic with a grafting end group. Is one with a narrow polydispersity ranging from 1 to about 1.15. In another aspect of this embodiment said styrenic polymer with a grafting group with a narrow polydispersity is polystyrene. An example of a suitable grafting end group is an alcohol or benzylic alcohol end group.

### EXAMPLES

Reference will now be made to more specific embodiments of the present disclosure and experimental results that provide support for such embodiments. The examples are given below, to illustrate more fully the disclosed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

Although the disclosed and claimed subject matter has been described and illustrated with a certain degree of particularity, it is understood that the disclosure has been made only by way of example, and that numerous changes in the conditions and order of steps can be resorted to by those skilled in the art without departing from the spirit and scope of the disclosed and claimed subject matter.

### Chemicals

All chemicals unless otherwise indicated were purchased from Sigma Aldrich (3050 Spruce St., St. Louis, MO 63103) and used as received. 4-(4-Butylphenylazo(phenol) was obtained from TCI. 6-Bromhexan-1-ol was obtained from Combi-Blocks. THF stabilizer free was obtained from Acros. Sec-BuLi w=6% in cyclohexane was obtained from Albemarle. Methyl methacrylate (MMA) was used after filtration over basic aluminum oxide. LC monomers were synthesized as described below. Chemicals used in anionic polymerization were purified as described in the literature (e.g., Techniques in High-Vacuum Anionic Polymerization″ By David Uhrig and Jimmy Mays and Journal of Polymer Science: Part A: Polymer Chemistry, Vol. 43, 6179-6222 (2005))

### Instrumentation.

Polymer solution spin coating was done on an Ossila Spin Coater 3.0. Annealing was done on an IKA C-MAGHS 7 control hot plate. Scanning electron micrographs (SEM) pictures were obtained with a Magellan Extra-High Resolution Scanning Electron Microscope 400L. Atomic force microscopy (AFM) pictures were obtained on a Bruker Dimension Icon XR Scanning Probe Microscope. GISAXS analysis of self-assembled and annealed block copolymer films to obtain L₀ data was done on a homemade system at Hamburg University made of the following elements: Incoatec IpS High Brilliance x-ray source, Quazar Montel multilayer mirrors, Scatex scatterless pinhole collimation, Rayonix SA 165 CCD-detector. Measurement conditions: 0.154 nm wavelength, 700 μm beam diameter at sample, 1.6 m sample-detector distance for SAXS, fully evacuated beam path (except sample area), 3600 s accumulation time per sample, 0.2-degree incident angle for GISAXS. VASE ellipsometry measurements were obtained with a J. A. Woollam alpha SE ellipsometer and the Complete Ease software. Plasma oxygen etching experiments were done with a Diener Pico Plasma Asher. The plasma etching conditions employed to etch block copolymer films were Power=100 Watt (W.). Gel permeation chromatography was done with a GPC-MALS for absolute Mₙ measurement. The system contained Agilent Degasser G7122A, Pump G71101B, Autosampler G7129A, Column oven MCT G7116A, and detectors VWD G7114A, Wyatt Dawn 8 MALS, Whatt Optilab RI. Polystyrene standard of 10 mg 30 kDa dissolved in 2 mL THF. 1H NMR spectra were acquired on a Bruker Advance 500 MHz spectrometer.

### Working Monomer Synthesis Examples: Synthetic Methods for Liquid Crystal Monomers MA-Cx-Azobutyl (MA-Cx-Azobutyl(x-(4-((4-butylphenyl)diazenyl)phenoxy)alkyl(Cx alkyl 6, 8, 11) methacrylate

The MA-Cx-Azobutyl monomers Cx alkyl 6, 8, 11 were made by reaction as shown in Scheme 1 as described below:

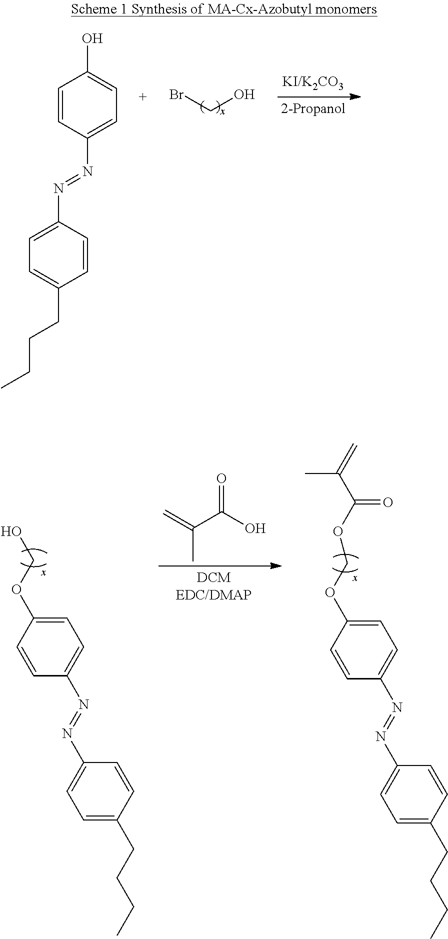

The following description related to the case of C6, where n=6: 6-(4-((4-butylphenyl)diazenyl)phenoxy)hexan-1-ol

In a three-neck round-bottomed flask equipped with mechanical stirrer, condenser and nitrogen inlet and outlet, 4-((4-butylphenyl)diazenyl)phenol (0.5 mol, 127.16 g, 1 equiv.) was dissolved in isopropanol (1.6 L). To the clear solution, potassium carbonate (0.75 mol, 103.65 g, 1.25 equiv.) and potassium iodide (60 mmol, 9.96 g, 1 equiv.) were added. Afterwards, 6-bromo-hexan-1-ol (0.625 mol, 82 mL, 1.25 equiv.) was introduced, and the mixture stirred under reflux overnight. The mixture was allowed to cool down to 50° C. room temperature and filtered off to remove the salts. The filtrate was then concentrated and the solid was further purified by recrystallization from heptane: isopropanol (1:1) to afford 139 g product (yield: 78.4%).

In an argon atmosphere, 6-(4-(p-tolyldiazenyl)phenoxy)hexan-1-ol (0.2 mol, 70.9 g, 1 equiv.) was dissolved in dry dichloromethane (DCM) (1.8 L). Afterwards, methacrylic acid (0.46 mol, 39.6 g, 2.3 equiv.) and 4-(dimethylamino)pyridine (DMAP) (0.06 mol, 7.33 g, 0.3 equiv.) were added, and the mixture was cooled down with an ice bath to 0° C. N-(3-dimethylaminopropyl)-N-ethylcarbodiimide (0.5 mol, 77.6 g, 2.5 equiv.) was slowly added and the reaction mixture was allowed to slowly warm up to room temperature and stirred overnight. The solvent was removed under reduced pressure and crude product was purified via silica gel column to receive 65 g of the azomonomer as a yellow solid (yield: 77%).

### Working Polymerization Examples: Synthetic Methods for PMMA-b-P[MA-Cx-Azobutyl]poly(MA-C6-Azobutyl(polym((E)-x-(4-((4-butylphenyl)diazenyl)phenoxy)alkyl(Cx alkyl 6, 8, 11) (x=6, 8, 11) Polymerization

LC-BCPs which were synthesized by RAFT and anionic polymerization had the following repeat units structures: PMMA-b-P[MA-Cx-Azobutyl], poly(MA-C6-Azobutyl(polym((E)-x-(4-((4-butylphenyl)diazenyl)phenoxy)alkyl(Cx alkyl 6, 8, 11) where x=6, 8, 11, and as shown schematically, without end group details, and only showing the A and B repeat units chemical structures, as follows in structures (V-1), (V-2) an (V-3).

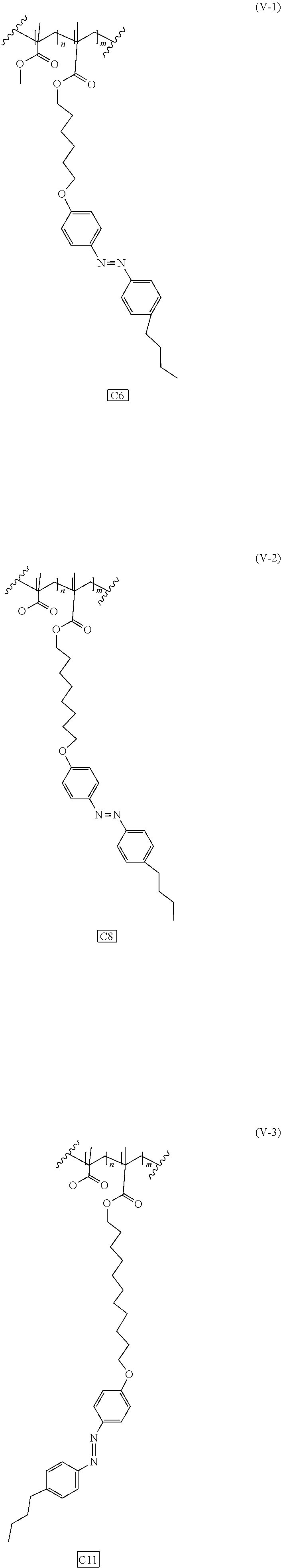

### RAFT Polymerization Method (Schemes 2 &3):

The Polymer Synthesis procedure for all Examples began with polymerization of the first block, PMMA. Methylmethacrylate (MMA) monomer (49.942 mmol) is filtered over basic aluminum oxide. The amount of change transfer agent (CTA) which was used in the preparation of the block copolymer; (in these instances 1-cyano-1-methylethyl benzenecarbodithioate was used), was chosen to bring about the desired Mₙ. Specifically, the amount of AIBN was chosen with proportionality to the CTA (CTA:AIBN about 1:3), for example in the polymerization example the range of AIBN for PMMA block was 0.04 to 0.19 mmol; and the range of the second block copolymerization is 0.01 to 0.07 mmole. Thus, the mmol amount of the AIBN determines the Mₙ of the polymer as reported in Table 1) were pumped under vacuum in a sealed glass ampule, and then Argon or Nitrogen is introduced. MMA and anisole were added. The vessel was stirred overnight at 70° C. Then the solution was cooled to room temperature and polymer is precipitated with 3× antisolvent (methanol) before filtration over Buchner funnel. Dissolution in anisole or toluene and precipitation in methanol was followed by filtration which was repeated twice more. Finally, the filtrated polymer was dried in a vacuum oven at 40-50° C.

TABLE 1
mmole amounts of AIBN employed
for different Block Copolymers

| | mmol AIBN | mmol AIBN |
|---|---|---|
| Polymer ID | Block A | Block B |
| EX 1 | 0.07 | 0.02 |
| EX 2 | 0.08 | 0.03 |
| EX 3 | 0.06 | 0.01 |
| EX 4 | 0.04 | 0.01 |
| EX 5 | 0.10 | 0.02 |
| EX 6 | 0.13 | 0.02 |
| EX 7 | 0.07 | 0.01 |
| EX 8 | 0.19 | 0.03 |
| EX 9 | 0.12 | 0.06 |
| EX 10 | 0.04 | 0.05 |
| EX 11 | 0.04 | 0.07 |
| EX 12 | 0.05 | 0.01 |
| COMP EX 1 | 0.08 | 0.02 |
| COMP EX 2 | 0.11 | 0.02 |

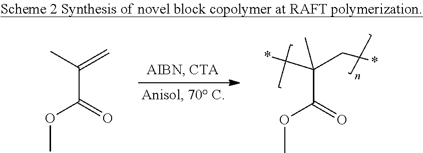

The second block was added in the general following way. The second monomer (MA-Cx-Azobutyl), AIBN, and the PMMA homopolymer described above were pumped under vacuum in a sealed glass ampule, and then Argon or Nitrogen was introduced. Degassed anisole was added by syringe. This mixture in the reaction vessel was stirred overnight at 70° C. Then the solution was cooled to room temperature and the precipitation procedure was repeated as for the homopolymer, described above. Table 1 gives a summary of the properties of the polymers which were made in this fashion. The relative proportions of the two repeat units as shown in Table 1, reflect the mole ratio of the MMA and MA-Cx-Azobutyl employed.

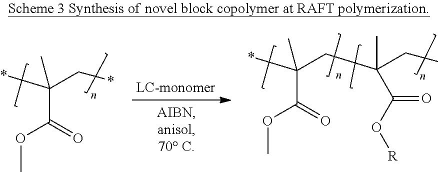

### Anionic Polymerization Method (Scheme 4):

Precursors were prepared in the following way. MMA monomer (103.280 mmol) was filtered over aluminum oxide and stored with molecular sieve in refrigerator. The same preparation was done for the anion carrier, 1,1-diphenylethylene (DPE). The MA-Cx-Azobutyl monomer was dissolved in toluene and stirred with calcium hydride for 3 hours, before filtration over aluminum oxide.

Each monomer was transferred to an ampule, degassed, and flushed with Argon three times. The mole ratio of the amount of MA-Cx-Azobutyl monomer employed versus MMA was reflected in the proportion of the corresponding repeat units as shown in Table 1. Reaction apparatus containing LiCl was heated under vacuum, then cooled to room temperature. Under Argon, THF (inhibitor free) was introduced to the reaction apparatus, which was then cooled to −78° C. Initiator (sec-BuLi) was added until yellow color indicates absence of water, after which the apparatus is allowed to return to room temperature. Then apparatus was cooled again to −78° C. and sec-BuLi (e.g., 0.2 mmol) (was added via syringe and stirred for 5 min. (The moles of the sec-BuLi versus moles of monomers determined the Mₙ of the polymer as reported in Table 1.) DPE (The volume of DPE is predicated by the volume of sec-BuLi) was added and stirred for 5 min. Then MMA monomer ampule was opened to the apparatus and introduced at the rate of 1 drop/sec. When completed, the second monomer ampule was opened to the apparatus and introduced in the same way. Stirring commenced for 3 hours. Afterwards, 3 mL of degassed methanol were introduced to quench the reaction, which was allowed to reach room temperature overnight. The final product was precipitated in methanol, filtered, and dried in a vacuum oven.

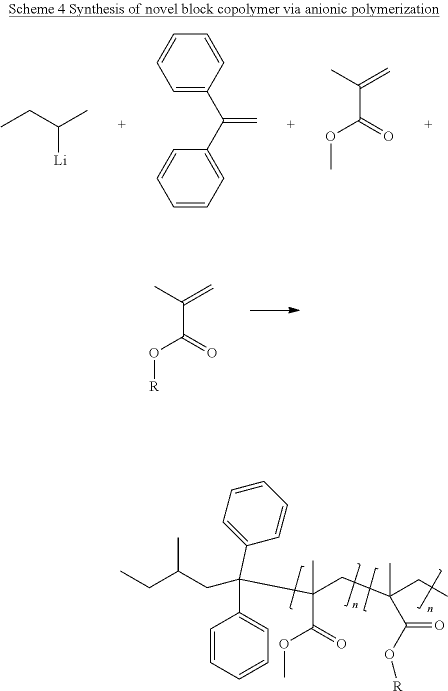

Tables 2a gives a summary of the different novel block copolymers which were made by either RAFT polymerization anionic polymerization using the general synthetic schemes outlined above but varying the load of the two different monomers to achieve the denoted ratio of these in these block copolymers and varying the amount of initiator to achieve different Mₙ values. Table 2b more specifically, gives a summary of anionic PMMA-b-P[MA C6 Azobutyl] polymer data for polymers with high Chi DSA.

TABLE 2a
Polymers with varying C-chain length and Mₙ by RAFT and
Anionic Polymerization (confirmed as lamellar by SAXS)

| | Polymerization | C- | | | repeat | repeat | total | | |
|---|---|---|---|---|---|---|---|---|---|
| Polymer | Type/LC | chain | Mₙ | | unit A = | unit B = | repeating | mol % | mol % |
| ID | end group | length | (kDa) | PDI | MMA | LC | units | A | B |
| EX. 1 | RAFT/n-Bu | 6 | 37 | 1.05 | 224 | 34 | 258 | 86.8% | 13.2% |
| EX. 2 | RAFT/n-Bu | 6 | 39 | 1.05 | 183 | 49 | 249 | 73.5% | 26.5% |
| EX. 3 | RAFT/n-Bu | 8 | 33 | 1.08 | 225 | 24 | 249 | 90.4% | 9.6% |
| EX. 4 | RAFT/n-Bu | 8 | 36 | 1.08 | 276 | 18 | 294 | 93.9% | 6.1% |
| EX. 5 | RAFT/n-Bu | 8 | 37 | 1.06 | 162 | 46 | 270 | 60.0% | 40.0% |
| EX. 6 | RAFT/n-Bu | 8 | 38 | 1.05 | 240 | 30 | 270 | 88.9% | 11.1% |
| EX. 7 | RAFT/n-Bu | 8 | 39 | 1.05 | 220 | 37 | 257 | 85.6% | 14.4% |
| EX. 8 | RAFT/n-Bu | 11 | 21 | 1.03 | 124 | 18 | 132 | 93.9% | 6.1% |
| EX. 9 | RAFT/n-Bu | 11 | 21 | 1.23 | 72 | 60 | 132 | 54.5% | 45.5% |
| EX. 10 | RAFT/n-Bu | 11 | 37 | 1.31 | 141 | 46 | 187 | 75.4% | 24.6% |
| EX. 11 | RAFT/n-Bu | 11 | 42 | 1.29 | 119 | 61 | 337 | 35.3% | 64.7% |
| EX. 12 | RAFT/n-Bu | 11 | 48 | 1.07 | 302 | 35 | 337 | 89.6% | 10.4% |
| EX. 13 | Anionic/n-Bu | 6 | 84 | 1.01 | 440 | 95 | 535 | 82.2% | 17.8% |
| EX. 14 | Anionic/n-Bu | 6 | 90 | 1.01 | 490 | 98 | 639 | 76.7% | 23.3% |
| EX. 15 | Anionic/n-Bu | 6 | 108 | 1.01 | 501 | 138 | 639 | 78.4% | 21.6% |
| EX. 16 | Anionic/n-Bu | 8 | 169 | 1.02 | 1011 | 162 | 1173 | 86.2% | 13.8% |

TABLE 2b
Polymers with high Chi Via Anionic LC BCB

| | | | | PDI | | L₀ thin |
|---|---|---|---|---|---|---|
| | Polymer- | C- | | BCP | Volume | film |
| Polymer | ization | Chain | Mₙ | (GCP | fraction | (nm, FFT |
| ID | Type | Length | (kDa) | MALS) | (MMA:LC) | AFM) |
| EX. 17 | Anionic/ | 6 | 35 | 1.007 | 42%:58% | 23 |
| | n-Bu | | | | | |
| EX. 18 | Anionic/ | 6 | 33 | 1.005 | 51%:49% | 24 |
| | n-Bu | | | | | |
| EX. 19 | Anionic/ | 6 | 29 | 1.002 | 50%:50% | 22 |
| | n-Bu | | | | | |
| EX. 20 | Anionic/ | 6 | 27 | 1.012 | 48%:52% | 19 |
| | n-Bu | | | | | |

### Comparative Examples: Synthetic Methods for PMMA-b-P[MA-C6-Azo-R](R=methoxy, cyano)

LC-BCPs for COMVIP EX. 1 and COMVIP EX. 2 (Table 3) were synthesized by RAFT polymerization, with the following structure: PIVMA-b-P[MA-C6-Azo-R], where R=Methoxy, Cyano in the same manner as EX. 1 except that the LC containing monomers were ones with a Methoxy or Cyano end group instead of n-Butyl. Structures (VI-1) and (VI-2) respectively shows the structures of these comparative block copolymers when the LC end group is methoxy or cyano.

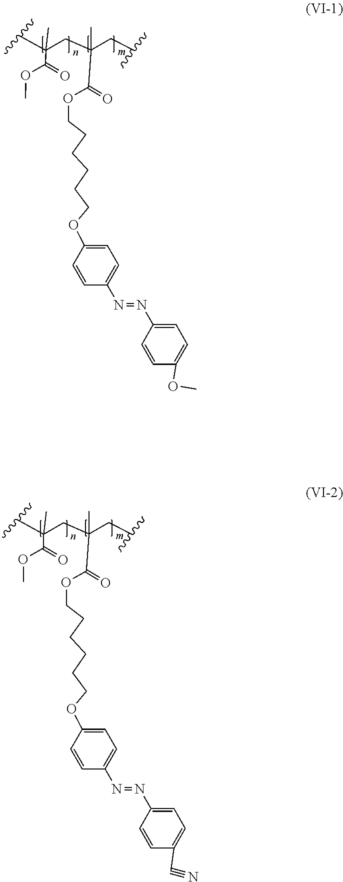

TABLE 3
RAFT Synthesis of PMMA-b-P[MA-C6-Azo-methoxy] and PMMA-b-P[MA-C6-Azo-cyano]

| | Polymerization | | | repeat | repeat | C- | total | | |
|---|---|---|---|---|---|---|---|---|---|
| Polymer | type/LC | Mₙ | | unit A = | unit B = | chain | repeating | mol % | mol % |
| ID | end group | (kDa) | PDI | MMA | LC | length | units | A | B |
| Comp | RAFT/Methoxy | 40.6 | 1.04 | 185 | 56 | 6 | 224 | 82.6% | 17.4% |
| EX. 1 | | | | | | | | | |
| Comp | RAFT/Cyano | 36.5 | 1.04 | 176 | 48 | 6 | 224 | 78.6% | 21.4% |
| Ex. 2 | | | | | | | | | |

### Working Examples for Standing Lamellar Fingerprints of Polymers, without the Use of Underlayers

Polymers from the working Examples in Table 1 were observed to form standing lamella on Silicon dioxide (SiOx) and (SiN) substrates with no underlayer.)

### Film Preparation Method:

Polymers were dissolved in toluene or PGMEA at wt. % values between 0.5% and 2.5%. Spin coating of 100 μL on sulfuric acid treated SiOx or untreated SiN substrates was done for 30 sec at 3000 rpm. Films were annealed between 150° C. and 250° C. for 10 min-4 hrs. All formulations containing the novel block copolymer treated in this manner were observed to form a Fingerprint pattern indicative of vertical orientation of the polymer block domains during the annealing process. As examples AFM pictures of this self-assembly are shown in FIG. 1, FIG. 2, FIG. 3, FIG. 4 and FIG. 5, respectively for Fingerprint patterns obtained after annealing a film of the copolymers of EX. 1, EX. 5, EX. 9, EX 15, EX. 16. However, all the block copolymer EX. 1 to EX. 16 were examined by AFM in this manner patterns, and these images were used to find the resultant L₀ as measured by GI-SAXS or from the fast fourier transform (FFT) of the AFM images are shown in Table 4. The range of block copoymer pitches achieved during annealing on SiO or SiN is 17-73 nm. The graph in FIG. 5 shows the dependency of L₀ on Mₙ of block copolymers EX. 1 to EX. 16.

Additionally, fingerprint patterns (FIG. 15) could be obtained using the polymers of EX. 17, 18, 19 and 20 (Table 2b) by spin casting a 1 wt. % solution of these over SiN and baking for 1 hour. The processing solvent employed to obtain these fingerprint patterns was anisole, xylene, and cyclopentanone, however PGMEA and toluene could also be employed. FIG. 15 left to right showed respectively, that the liquid crystal block copolymer of EX. 17, 18 and 19 gave good fingerprint patterns indicative of a vertical orientation during the annealing process. The liquid crytal block copolymer of EX. 20, while apparently a cylindrical BCP, using the same processing conditions, gave an AFM image consistent with the high Chi of this system with a center to center disctance of 19 nm (FIG. 15 bottom).

TABLE 4
Examples of Standing Lamellar Fingerprints
for polymers of each C-chain length

| | | L₀ (nm, | |
|---|---|---|---|
| Polymer | AFM Image | GISAXS) | Substrate |
| EX. 1 | See FIG. 1 | 23.3 | SiOx |
| EX. 5 | See FIG. 2 | 31 | SiN |
| EX. 9 | See FIG. 3 | 19 | SiOx |
| EX. 15 | See FIG. 4 | 49 | SiN |
| EX. 16 | See FIG. 5 | 73 | SiN |

The graph in FIG. 1 shows the dependency of L₀ on Mₙ of the block copolymers.

In contrast, the comparative Examples COMP EX. 1 and COMP EX. 2 when formulated and annealed in the same manner as EX. 1 to 16 on either SiO or SiN self assembly of block copolymer domains in a vertical orientation with respect to these substrates. Table 5 summarizes the results obtained with these comparative copolymers. FIG. 6 and FIG. 7, respectively shows, the SEM observed the comparative block copolymers with a methoxy or a cyano LC capping group.

TABLE 5
COMP EX. 1 and COMP EX. 2 Annealing on a Substrate

| | | L₀ (nm, | |
|---|---|---|---|
| Polymer | AFM Image | SAXS) | Substrate |
| COMP. | See FIG. 7 | No lamellar | SiN |
| Ex. 1 | | structure | |
| | | observed | |
| COMP | See FIG. 8 | Laying | SiOx |
| Ex. 2 | | lamellar | |
| | | structure | |

From this experiment it was observed that the LC end group has significantly impact on the interaction between the LC block and the substrate interface achieving standing lamellar structure fingerprint. AFM data shows that when the LC end group are hydrophilic such Cyano and Methoxy, no standing lamellar perform and 1 block has preferential interaction with substrates. However, when the LC end group are hydrophobic, such butyl, standing lamellar structure observed. Meaning that the interaction of PMMA block and LC block with substrate are equal.

### Working Examples DSA of Polymers Over Graphoepitaxy Prepatterned Substrates

Graphoepitaxy substrates were fabricated by E-beam lithography. Substrates were characterized by plateaus and trenches in Si, with dimensions of 40/40, 60/60, 80/80, and 100/100 nm width of plateau/trench (line/space, L/S), and trench depth of ˜25 nm. After sulfuric acid treatment, spin coating of polymer solutions was performed as on flat substrates as well as annealing. DSA was observed in the trenches. FIG. 9 shows AFM (Atomic Force Microscopy) pictures obtained for DSA of the block copolymer of EX. 1 on the aforementioned Graphoepitaxy Substrates with trench/plateau dimensions of 40/40, 60/60, 80/80, 100/100 nm from left to right.

FIG. 16 shows an AFM of Graphoepitaxy obtained from PMMA-b-P[MA C6 Azobutyl] with L₀ 23 nm (EX. 17, Mₙ 35 kDa), 1 wt. % 190° C. 1 hr over 80 nm trench/plateau in SiOx. These show an effective L₀ of 20.8 nm. These were obtained by spin coating a 0.45-1.2 wt. % solutions over topographical substrates of trench/plateaus in Silicon oxide of trench width: plateau width 1:1, where the widths where 40, 60, 80, and 100 nm. After, annealing at 190° C. 1 hr. the BCP was seen to align in the trenches and, at higher wt. %, also over the plateaus. The effective L₀ observed was 20.8 nm, even though the L₀ of observed for the corresponding fingerprint pattern (FIG. 15) was 23 nm.

### Working Examples DSA of Novel Block Copolymer EX. 1 to 16, Over Chemoepitaxy Prepatterned Substrates

It was observed that partial chemoepitaxy DSA could be obtained the novel block copolymer of r EX 1 to 13 I these were annealed over a thin guiding chemoepitaxy stripes of crosslinked PMMA with a pitch of 90 nm and width of 36 nm on SiN. FIG. 10 shows the AFM picture obtained when EX. 15 was annealed over this guiding chemoepitaxy on SiN. This AFM picture shows the trans-prepattern pitch for DSA of the annealed film of block copolymer EX. 15 which persist for a significant distance before disorder begins.

When annealing self-assembly of a film of block copolymer EX. 15 was done on a chemoepitaxy pattern of crosslinked PMMA with a pitch of 96 nm and width of 31 nm of guiding stripes of crosslinked PMMA where these guiding stripes had a thickness of 4.8 n. Chemoepitaxy DSA alignment without any disorder and with 2-time multiplication was observed which correspond to GISAXS L₀ data discussed above. FIG. 11 shows SEM pictures of this chemoepitaxy directed self-assembly of an annealed film of this polymer at low and high AFM magnification.

Additionally, FIG. 17, 18, show AFM images of chemoepitaxy of PMMA-b-P[MA C6 Azobutyl] with L₀ 23 nm (EX. 17, Mₙ 35 kDa). For these Figures, this block copolymer was coated at 1-1.2% over different chemical prepattern of crosslinked PMMA and then annealing 190° C. 1 hr. Specifically. FIG. 17 show DSA over pitches of 90 nm of crosslinked PMMA (3.9 L₀), width 26 nm and FIG. 18 shows DSA over pitches xPMMA of pitch 112 nm (4.9 L₀), width 26 nm. These were demonstration of 4× and 5× pitch multiplications, respectively. Further, DSA was also observed with guiding strip width (W) of W=1−1.4 L₀.

### Working Example Etch Selectivity of Polymers

Homopolymers of PMMA(polymethyl methacrylate), P[MA-C6-Azobutyl](polym((E)-6-(4-((4-butylphenyl)diazenyl)phenoxy)hexyl methacrylate)), and P[MA-C11-Azobutyl](poly((E)-11-(4-((4-butylphenyl)diazenyl)phenoxy)undecyl methacrylate)) were deposited as films and exposed to plasma oxygen etching. The etch rate of each homopolymer was measured by VASE ellipsometry and showed a difference in etch rate between the liquid crystal homopolymers and the PMMA of a factor of 2 (FIG. 12).

SEM Imaging of an LC-BCP before and after oxygen plasma etching of annealed self-assembled film of block copolymers EX. 1 to 16, showed relative removal of the PMMA with respect to the liquid crystal block after etching. FIG. 13 shows a continuous film after annealing of the self-assembled block copolymer EX. 11. FIG. 14 shows the same film post etch were the self-assembled PMMA block domains are removed more selectively than the methacrylate block domains with a pendant LC moiety.

### Prophetic Synthesis Examples Set 1: Synthetic Methods for PMMA-b-P[MA-Cx-Azobutyl] (x=3-12) Polymerization

As in EX. 1 to EX. 16 which had spacer chain lengths of C-6. C-8 and C-11 other copolymers of PMMA-b-P[MA-Cx-Azobutyl](x=3-12) which have other chain lengths of L in structure (II), in the range of C-3 to C-12 could be synthesized in a similar way, with the monomer of corresponding C-chain length as was done for the polymer of EX. 1 to 16.

### Prophetic Self Assembly Examples Set 2: Standing Lamellar Fingerprints of Inventive Copolymers with Pitches as Small as 5 nm, without the Use of Underlayers

The copolymers of Prophetic Examples 1 PMMA-b-P[MA-Cx-Azobutyl](x=3-12) would be expected could be expected to form standing lamellar fingerprints without the use of underlayers. The polymer of EX. 1 to EX. 16 demonstrated the ability to achieve as low as 17 nm pitch for a polymer with Mₙ of 21 kDa. Since said polymers are high χ materials, even low Mₙ of these novel polymers can undergo phase separation. This enables the achievement of especially low pitches. It is predicted that these polymers can be synthesized at Mₙ<21 kDa and provide L₀ of down to 5 nm.

### Prophetic Etching Examples Set 3: Etch Selectivity of Inventive Copolymers

The polymers of Prophetic Examples set 1 PMMA-b-P[MA-Cx-Azobutyl](x=3-12) would be expected to show etch selectivity between the blocks containing pendant liquid crystal groups and the poly(methyl methacrylate) (PMMA) blocks, similar to what was observed to be the case in the homopolymer etching experiments of FIG. 12 which compared C6 and C11 homopolymers to PMMA homopolymer and the etching experiments shown in FIGS. 6 and 7 for a Self-Assembled film of the block copolymer of EX. 11.

### Prophetic Etching Multi Pitch Examples Set 4: Multi-Pitch DSA Using Inventive Copolymers

The block copolymer of EX. 1 to 16 showed potential for multi-pitch DSA, in which the same polymer can compress and stretch to create different pitches depending on the dimensions of the prepattern. For example, 2 lines of the same polymer were repeated in both the 60 nm trench and the 80 nm trench, indicating a degree of flexibility. It is predicted that up to 70% expansion (stretch) capability from the natural period of the polymer. It is also predicted that when the LC capping group (R₃) in Structure (II) in increased from C-4 for instance to C-7 and C-8, this would also contribute to the ability of the block copolymer to expand and compress leading to a wider capability of multi pitch directed self-assembly. Such copolymer could be made in the same manner as the C-4 capped block copolymers of EX. 1 to 16.

### Prophetic Examples for Reduced Defectivity Set 5: Low Defectivity in DSA Pattern Transfer Using Said Polymers

Based on the working Examples for these inventive block copolymers it is expected that the these will for future application in actual pattern transfer on integrated circuits would have especially low defectivity (such as dislocations). This is because the use of neutral layers generally required for DSA eventually increases defectivity during and after the etch process. Since these inventive block copolymers do not require the use of neutral layers, said inventive block copolymers should result in lower defectivity.

### Prophetic Examples for Reduced Defectivity Synthesis and Use of Polymers where R′ is a C-3 to C-8 Linear Alkyl

The above-described working examples showed the potential for multi-pitch DSA, in which the same polymer can compress and stretch to create different pitches depending on the dimensions of the prepattern. For examples, 2 lines of the same polymer were repeated in both the 60 nm trench and the 80 nm trench, indicating a degree of flexibility. We predict up to 70% expansion (stretch) capability from the natural period of the polymer. In addition, it is predicted that a subset of polymers with side chains to the liquid crystal or end groups to the liquid crystal of C=3-8, and preferably, C-7 to C-8, which could contribute to the ability of the polymer to expand and compress. The following are prophetic examples on how to make a specific example of this type of material.

This prophetic example gives a specific example of how this variant of the inventive block copolymers which have a branching C-3 to C-8 alkyl (a.k.a. R′ C-3 to C-8), could be made. The specific example is for C-8 branched MA-C6-Azobutyl repeat unit and an MMMA repeat unit could be made showing the synthesis of the precursor, the methacrylate monomer and its subsequent polymerization. Other C-X branched MA-Cx-Azoalkyl(Cx′) monomer [a.k.a in structure (I) (X=C-5 to C-8 a.k.a. R′-linear alkyl branching group; x=5 to 12 a.k.a. L linear alkylene C-5 to 12; and Cx′=3 to 8, a.k.a. R₃=C-3 to C-8 linear alkyl)-precursors, monomers and block copolymer could be made in a similar fashion. Scheme 5 shows the scheme for the synthesis of the precursor and the C-8 branched MA-C6-akobutyl repeat units. These other C-X branched MA-Cx-Azobyl could be prepared in a similar fashion.

### Anionic Polymerization of Branched Alkyl PMMA-b-[MA-C6 Azobutyl]Prophetic Synthesis of 2-(4-bromobutyl)-decan-1-ol Step 1 (Scheme 5)

Decanal (TCI, 10.30 mol, 1609 g, 1.2 equiv) is reacted with 1,4-Dibromobutane (TCI, 8.58 mol, 1853 g, 1 equiv) in 4N NaOH solution (7 L) in the presence of a water-soluble calix[n] arenes catalyst (TAC₄M catalyst 0.013 equiv). After reaction the aqueous reaction mixture can be extracted with methylene chloride, the organic layer washed with water and dried with a desiccant such as molecular sieves of anhydrous MgSO₄, the methylene chloride removed, and the crude product purified by using column chromatography or recrystallization to produce a predicted yield of about 8% yield (200 g) of 2-(4-bromobutyl) decanal which has a predicted melting point of 60.7° C. This reaction procedure was adapted from Adv. Synth. Catal. 2002, 344, 370 to 378.

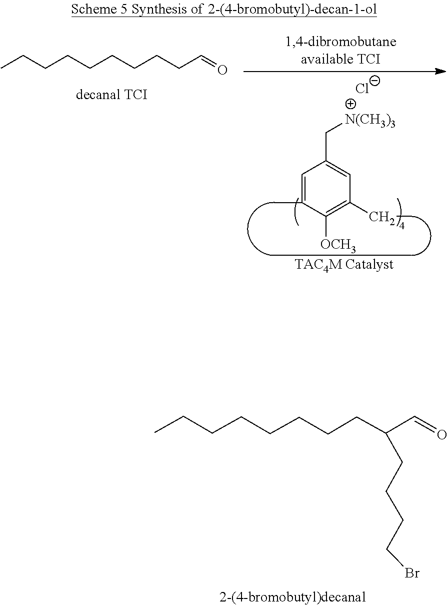

### Prophetic Synthesis of 2-(4-bromobutyl)-decan-1-ol Step 2 (Scheme 6)

The carbonyl on 2-(4-bromobutyl) decanal from step 1 is reduced by NaBH₄ in methanol to produce the alcohol precursor for the monomer synthesis below. 2-(4-bromobutyl) decanal (0.69 mol, 200 g, 1 equiv) is dissolved in methanol (360 mL), is cooled to 0° C.; then NaBH₄ (0.69 mol, 26.1 g, 1 equiv) is added in portions under vigorous stirring. After addition of NaBH₄ is complete, the solution is heated to 40° C. overnight. After reaction, the methanol is removed with a roto evaporator and the residue dissolved in methylene chloride, the organic layer washed with water, dried with a desiccant such as molecular sieves of anhydrous MgSO₄, the methylene chloride is removed and the crude product purified by using column chromatography to produce with a predicted yield of about 160 gr (˜80% yield) of 2-(4-bromobutyl)-decan-1-ol with a predicted melting point of 79.4° C. and a predicted C-13 NMR in ppm as shown in Scheme 6.

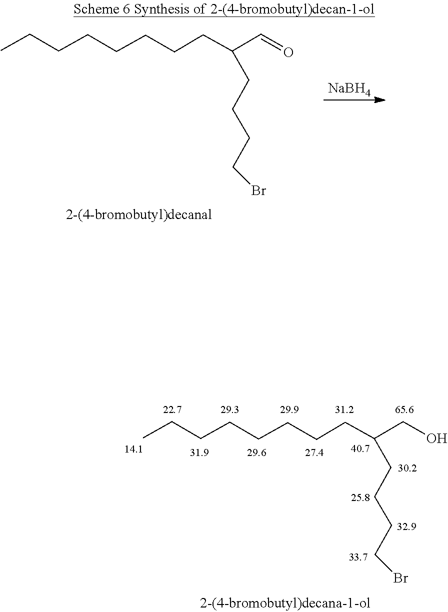 [SMILES: CCCCCCCCC(C=O)CCCCBr ; "NaBH4" ; CCCCCCCCC(CO)CCCCBr]

### Prophetic Synthesis of the Branched C-8 Branched MA-C6 Azobutyl Monomer ((E)-2-(4-(4-((4-butylphenyl)diazenyl)phenoxy)butyl)decyl methacrylate) is as Follows: (Scheme 7)

In a three-necked round-bottom flask equipped with mechanical stirrer, condenser and nitrogen inlet and outlet, 4-((4-butylphenyl)diazenyl)phenol (0.5 mol, 127.16 g, 1 equiv) is dissolved in isopropanol (1.6 L). To the clear solution, potassium carbonate (0.75 mol, 103.65 g, 1.25 equiv.) and potassium iodide (60 mmol, 9.96 g, 1 equiv.) were added. Afterwards, 2-(4-bromobutyl)-decan-1-ol (0.625 mol, 183.31 g, 1.25 equiv.) is introduced, and the mixture stirs under reflux overnight. The mixture is allowed to cool room temperature and is filtered off to remove salts. The filtrate is then concentrated and the solid is further purified by recrystallization from heptane:isopropanol (1:1) to afford an expected yield of 233.35 g product (if 100% yield) of (E)-2-(4-(4-((4-butylphenyl)diazenyl)phenoxy)butyl)decan-1-ol (MW: 466.71)

In an argon atmosphere, the (E)-2-(4-(4-((4-butylphenyl)diazenyl)phenoxy)butyl)decan-1-ol (0.2 mol, 93.3 g, 1 equiv) is dissolved in dry dichloromethane (1.8 L). Afterwards, methacrylic acid (0.46 mol, 39.6 g, 2.3 equiv) and 4-(dimethylamino)pyridine (0.06 mol, 7.33 g, 0.3 equiv.) are added, and the mixture is cooled down with an ice bath to 0° C. N-(3-dimethylaminopropyl)-N′-ethylcarbodiimide (0.5 mol, 77.6 g, 2.5 equiv.) is slowly added and the reaction mixture is allowed to slowly warm up to room temperature and stir overnight. The solvent is removed under reduced pressure and crude product is purified via silica gel column to yield 106.95 g of (E)-2-(4-(4-((4-butylphenyl)diazenyl)phenoxy)butyl)decyl methacrylate as a solid (if yield 100%) (MW 534.79). FIG. 7 shows the predicted C-13 NMR spectra in ppm for the final product.

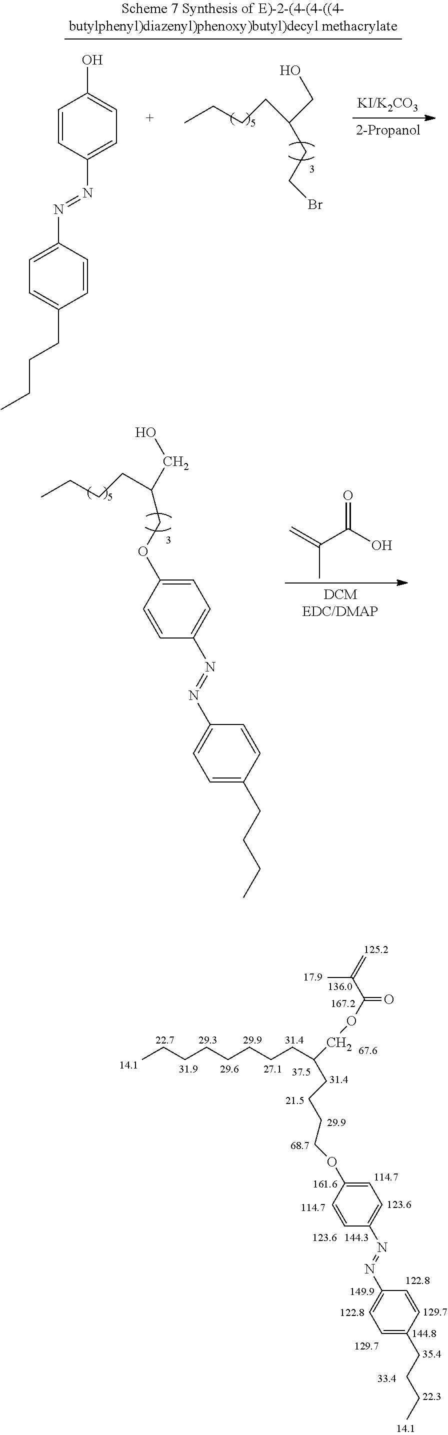

### Anionic Polymerization of E)-2-(4-(4-((4-butylphenyl)diazenyl)phenoxy)butyl)decyl methacrylate with Methyl Methacrylate

Methyl methacrylate (MMA) monomer (103.280 mmol) is filtered over aluminum oxide and stored with molecular sieve in refrigerator. The same preparation is done for the anion carrier, 1,1-diphenylethylene (DPE). The branched MA-C6-Azobutyl monomer, E)-2-(4-(4-((4-butylphenyl)diazenyl)phenoxy)butyl)decyl methacrylate, is dissolved in toluene and stirred with calcium hydride for 3 hours, before filtration over aluminum oxide.

Each monomer is transferred to an ampule, degassed, and flushed with Argon three times. The mole ratio of the amount of branched MA-C6-Azobutyl monomer employed versus MMA is in the range of 85%:15% to 15%:85%. Reaction apparatus containing LiCl is heated under vacuum, then cooled to room temperature. Under Argon, THF (inhibitor free) is introduced to the reaction apparatus, which is then cooled to −78° C. Initiator (sec-BuLi) is added until yellow color indicates absence of water, after which the apparatus is allowed to return to room temperature. Then apparatus is cooled again to −78° C. and sec-BuLi (e.g., 0.2 mmol) (is added via syringe and stirred for 5 min. The moles of the sec-BuLi versus moles of monomers determines the Mₙ of the polymer. DPE (the volume of DPE is predicated by the volume of sec-BuLi) is added and stirred for 5 min. Then MMA monomer ampule is opened to the apparatus and introduced at the rate of 1 drop/sec. When completed, the second monomer ampule is opened to the apparatus and introduced in the same way. Stirring commences for 3 hours. Afterwards, 3 mL of degassed methanol are introduced to quench the reaction, which is allowed to reach room temperature overnight. The final product is precipitated in methanol, filtered, and dried in a vacuum oven.

### Prophetic Synthesis of the Branched the Branched (C3) MA-C6 Azobutyl monomer)(E)-9-(4-((4-butylphenyl)diazenyl)phenoxy)nonan-4-yl methacrylate) (Scheme 8)

In a three-necked round-bottom flask equipped with mechanical stirrer, condenser and nitrogen inlet and outlet, 4-((4-butylphenyl)diazenyl)phenol (0.5 mol, 127.16 g, 1 equiv) is dissolved in isopropanol (1.6 L). To the clear solution, potassium carbonate (0.75 mol, 103.65 g, 1.25 equiv.) and potassium iodide (60 mmol, 9.96 g, 1 equiv.) were added. Afterwards, 9-bromononan-4-ol (0.625 mol, 139.5 g, 1.25 equiv., available from Aurora Building Blocks 4) is introduced, and the mixture stirs under reflux overnight. The mixture is allowed to cool room temperature and is filtered off to remove salts. The filtrate is then concentrated and the solid is further purified by recrystallization from heptane:isopropanol (1:1) to afford 232 g product (assuming: 100% yield) of this material which has a predicted C-13 NMR of 14.1 ppm (CH₃ in butyl), 22.3 μm (CH₂ in butyl), 33.4 μm (CH₂ in butyl), 35.4 ppm (CH₂ in butyl), 144.8 ppm (quaternary aromatic C attached to butyl), 129.7 (CH aromatic in aromatic moiety attached to butyl), 122.8 (CH aromatic in aromatic moiety attached to butyl), 149.9 (quaternary aromatic C attached to N═N moiety in aromatic group with OH functionality), 145.3 ppm (quaternary aromatic C attached to N═N in aromatic group with OH functionality), 124.4 μm (CH aromatic in aromatic group with OH functionality), 116.2 ppm (CH aromatic in aromatic group with OH functionality) and 160.7 ppm (quaternary aromatic C attached to OH). Scheme 8 shows the predicted C-13 NMR peaks in ppm of the final product.

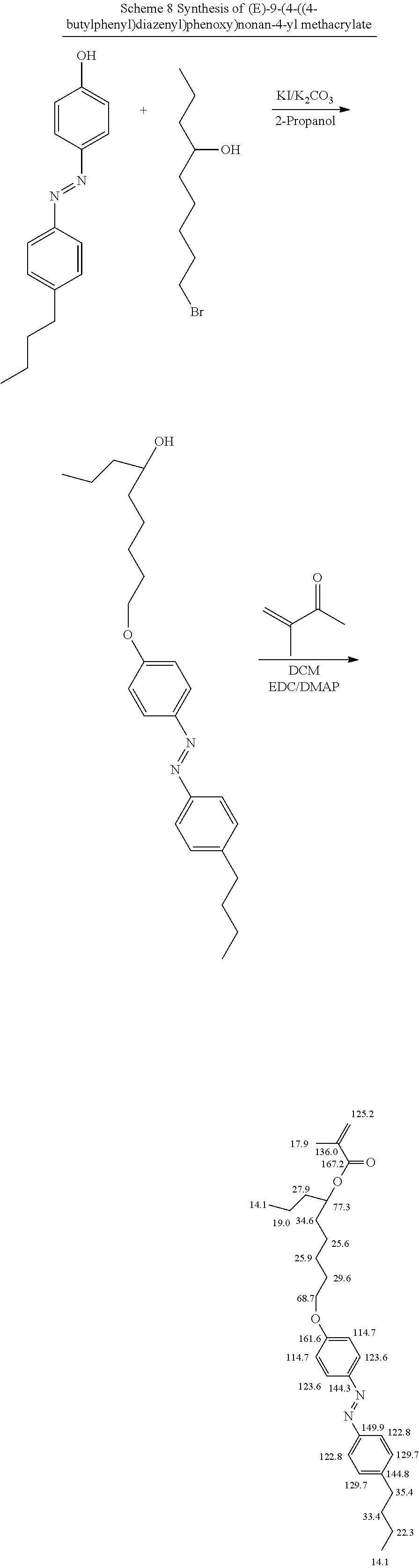

### Anionic Polymerization of (E)-9-(4-((4-butylphenyl)diazenyl)phenoxy)nonan-4-yl methacrylate with Methyl Methacrylate

This anionic polymerization is performed described above for the copolymerization of methyl methacrylate with (E)-2-(4-(4-((4-butylphenyl)diazenyl)phenoxy)butyl)decyl methacrylate replacing the latter with an equimolar amount of) (E)-9-(4-((4-butylphenyl)diazenyl)phenoxy)nonan-4-yl methacrylate).

The foregoing description is intended primarily for purposes of illustration. Although the disclosed and claimed subject matter has been shown and described with respect to an exemplary embodiment thereof, it should be understood by those skilled in the art that the foregoing and various other changes, omissions, and additions in the form and detail thereof may be made therein without departing from the spirit and scope of the disclosed and claimed subject matter.

What is claimed is:

1. A block copolymer, which is an AB diblock copolymer with a first block A of structure (I) and a second block B of structure (II), wherein R and R₁ are individually selected from a C-1 to C-4 alkyl, n is the number of repeat units in structure (I), m is the number of repeat units in structure (II), and the mole % of repeat units of structure (I) ranges from about 35 mole % to about 94 mole %, and the mole % of repeat units of structure (II) ranges from about 6 mole % to about 65 mole % of the total moles of repeat units of structures (I) and (II), and the sum of the mole % of repeat units of structure (I) and (II) equals 100 mole %;
R₂ is selected from a C-1 to C-11 alkyl, L is a C-5 to C-12 linear alkylene, R₃ is selected from a C-3 to C-8 linear alkyl, and R′ is H or a C-3 to C-8 linear alkyl, and further wherein said block copolymer has a polydispersity of 1 to about 1.31, where said block copolymer is made by either RAFT polymerization or anionic polymerization, and has a polydispersity of 1 to about 1.13 and has an Mₙ ranging from about 8 kDa to about 25 kDa;

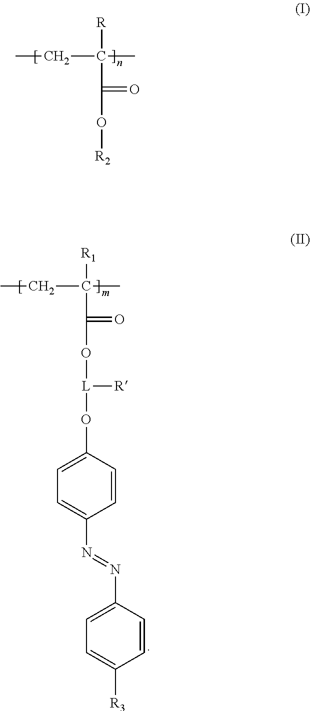

2-12. (canceled)

13. The block copolymer of claim 1, made by RAFT polymerization, which has structure (III), wherein Rr₁, is a C-1 to C-8 alkyl, Rr₂ is a C-1 to C-8 alkyl, and Rr is a cyano moiety (—CN) or a carbonylalkyl moiety (—C(═O)—Ri), wherein Ri is a C-1 to C-8 alkyl or an aryl moiety, and Rr₃ is an unsubstituted or substituted aryl moiety;

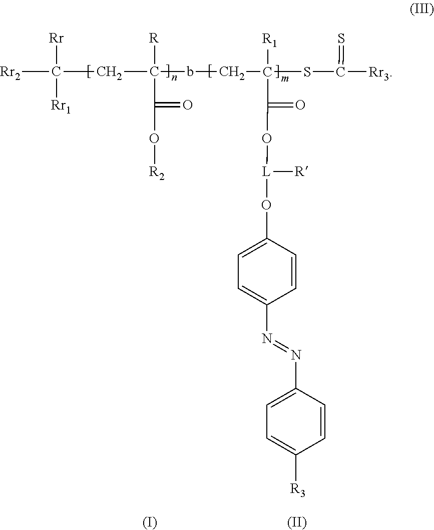

14.-22. (canceled)

23. The block copolymer of claim 13, wherein said block copolymer has structure (IIIa)

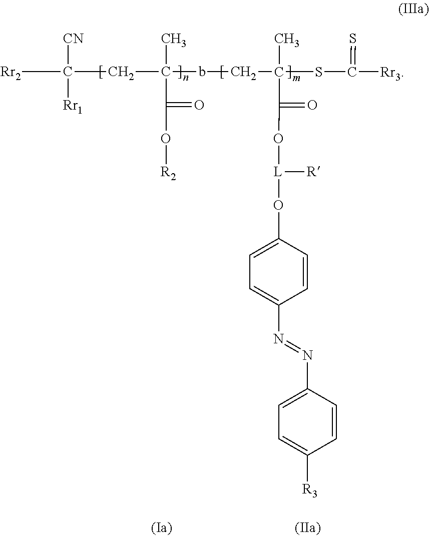

24.-42. (canceled)

43. The block copolymer of claim 23, wherein said block copolymer is one of structure (IIIb), wherein n′ and n″ are integers ranging independently from 0 to 11 and further where the sum of n′ and n″ ranges from 4 to 11.

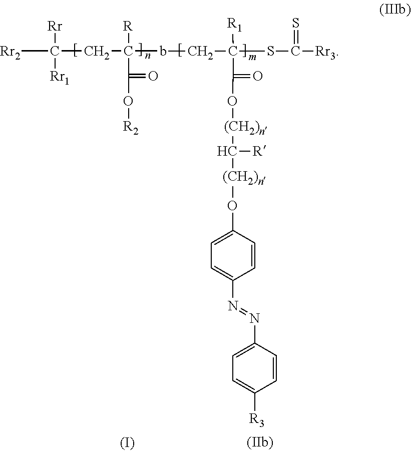

44. The block copolymer of claim 23, which has structure (IIIc)

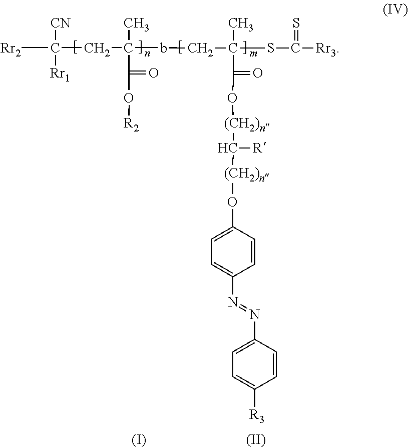

45.-113. (canceled)

114. The block copolymer of claim 1, which is made by anionic polymerization, and which has structure (IV), wherein Rₑ is a C-1 to C-8 alkyl, Rm and Rm₁ are individually selected from H, a C-1 to C-8 alkyl, a C-1 to C-8 alkoxy;

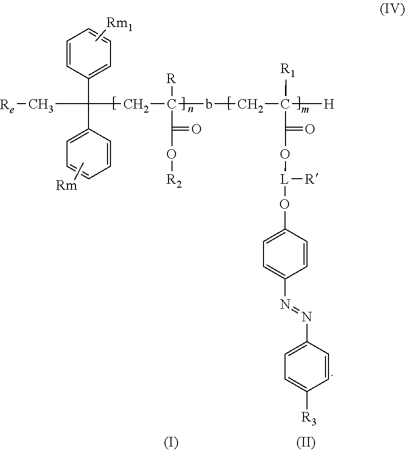

115.-127. (canceled)

128. The block copolymer of claim 1, wherein L is a C-5 linear alkylene.

129. The block copolymer of claim 1, wherein L is a C-6 linear alkylene.

130. The block copolymer of claim 1, wherein L is a C-7 linear alkylene.

131. The block copolymer of claim 1, wherein L is a C-8 linear alkylene.

132. The block copolymer of claim 1, wherein L is a C-9 linear alkylene.

133.-134. (canceled)

135. The block copolymer of claim 1, wherein L is a C-12 linear alkylene.

136. The block copolymer of claim 1, which has structure (IVa),

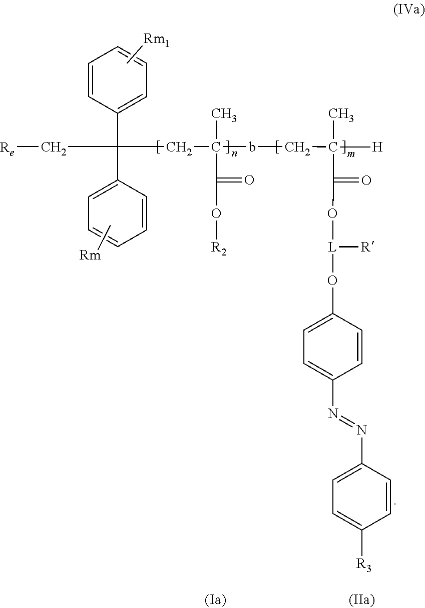

137.-153. (canceled)

154. The block copolymer of claim 136, wherein R′ is a C-3 to C-8 linear alkyl and said block copolymer is one of structure (IVb), wherein n′ and n″ are integers which independently range from 0 to 11 and further wherein the sum of n′ and n″ ranges from 4 to 11,

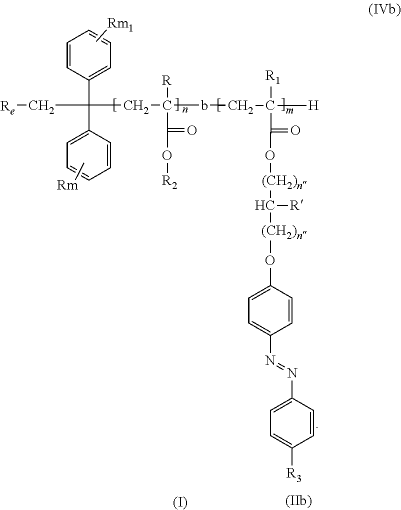

155. The block copolymer of claim 154, wherein said block copolymer is one of structure (IVc),

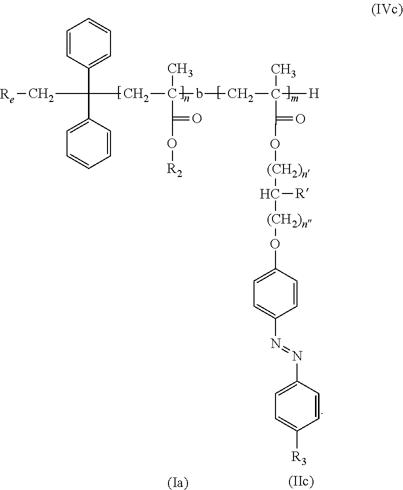

156.-223. (canceled)

224. A composition comprising the block copolymer of claim 1 and an organic spin casting solvent.

225.-231. (canceled)

232. A method of vertically orienting first and second block copolymer domains over an unpatterned substrate using a layer of a block copolymer having a periodicity of L₀ comprising the steps of:
a) forming a coating layer of a block copolymer with the composition of claim 224 on said unpatterned substrate which is not a neutral layer; and,
b) annealing the layer of the block copolymer to generate a non-zero positive integer number of first and second block copolymer domains, vertically oriented on said unpatterned substrate, which is selected from silicon, silicon dioxide, silicon nitride, silicon oxynitride.

233. (canceled)

234. A method of vertically orienting first and second block copolymer domains over a first patterned substrate where the height of topography of the pattern on the substrate is at least 0.7 times L₀ and aligning the domains with the pattern, using a coating comprising a block copolymer having a periodicity of L₀ comprising the steps of:
a-1) forming a coating layer of the block copolymer with the composition of claim 224, on said first topographical substrate, wherein the average thickness of the coating layer of the block copolymer is less than the height of the topography of the first topographical substrate, wherein the block copolymer layer is laterally confined by the topography; and,
b-1) annealing the block copolymer layer to generate first and second block copolymer domains, vertically oriented on said first patterned substrate, and confined within the recessed region, wherein
said patterned substrate comprises a pattern of a crosslinked polar polymer on a silicon, silicon dioxide, silicon nitride or silicon oxynitride substrate.

235. (canceled)

236. The method of claim 234, wherein said pattern of a crosslinked polar polymer is formed by patterning with UV radiation a coating of a copolymer of methyl methacrylate and 2-(vinyloxy)ethyl methacrylate on said substrate.

237. (canceled)

238. A method of vertically orienting, first and second block copolymer domains with a periodicity of L₀ over a second patterned substrate having a topographical pattern with the height of topography larger than 0.7 times L₀ and a pitch P₁ where the pitch P₁ is a non-zero positive integer multiplied by L₀, where further the bottom of the patterned substrate defined by said topography is not a neutral layer surface, and aligning the domains with the pattern comprising the steps of:
a-2) forming a coating layer of the block copolymer with the composition of claim 224, on said second patterned substrate, where the thickness of the coating layer of the block copolymer is more than the height of the topography of the second patterned substrate; and,
b-2) annealing the block copolymer layer to generate a non-zero positive integer number of first and second block copolymer domains vertically oriented on said second patterned substrate and aligning them to the second patterned substrate where the sum of vertically oriented domains is equal to or larger than the pitch the P₁ of the topographical pattern, wherein said patterned substrate comprises a pattern of a crosslinked polar polymer on a silicon, silicon dioxide, silicon nitride or silicon oxynitride substrate.

239. (canceled)

240. The method of claim 238, wherein said pattern of a crosslinked polar polymer is formed by patterning with UV radiation a coating of a copolymer of methyl methacrylate and 2-(vinyloxy)ethyl methacrylate on said substrate.

241. (canceled)

242. A method of vertically orienting first and second block copolymer domains over a substrate having a surface chemical prepattern which does not include a neutral layer area, having a pitch P₂, where the pitch P₂ is a non-zero positive integer multiplied by L₀ and aligning the domains comprising the steps of:
a-3) forming a coating layer of the block copolymer with the composition any-ene of claim 224, on the substrate having a surface chemical prepattern; and,
b-3) annealing the block copolymer layer to generate vertically oriented first and second block copolymer domains aligned with the substrate having a surface chemical prepattern having a pitch P₂, wherein
said surface chemical prepattern comprises polar areas and areas of silicon, silicon dioxide, silicon nitride or silicon oxynitride.

243. (canceled)

244. The method of claim 242, wherein said surface chemical prepattern is formed by patterning with UV radiation a coating of a copolymer of methyl methacrylate and 2-(vinyloxy)ethyl methacrylate on said substrate.

245. The method of claim 242, where said surface chemical prepattern is a patterned polar brush formed by first grafting onto a substrate a polar brush layer using a poly(methyl methacrylate) polymer functionalized at one of the polymer chains with a hydroxy group and then forming said chemical and then selectively etching it away using an overlying patterned photoresist as an etch barrier and stripping the photoresist.

246. (canceled)
